(19) United States
(12) Patent Application Publication
(10) Pub. No.: US 2025/0285999 A1
(43) Pub. Date: Sep. 11, 2025

(54) INTERPOSER MODULE INCLUDING EQUIPOTENTIAL PAD, PACKAGE STRUCTURE INCLUDING THE INTERPOSER MODULE AND METHODS OF FORMING THE SAME

(71) Applicant: Taiwan Semiconductor Manufacturing Company Limited, Hsinchu (TW)

(72) Inventors: Hung-Wei Tsai, Hsinchu (TW); Chih-Wei Wu, Zhuangwei Township (TW); Ying-Ching Shih, Hsinchu (TW)

(21) Appl. No.: 18/597,130

(22) Filed: Mar. 6, 2024

(51) Int. Cl. H01L 23/00; H01L 21/768; H01L 23/36; H01L 23/48; H01L 23/538

(52) U.S. Cl. CPC H01L 24/05; H01L 21/76898; H01L 23/36; H01L 23/481; H01L 23/5383; H01L 24/16; H01L 24/32; H01L 24/73; H01L 24/81; H01L 2224/022; H01L 2224/02372; H01L 2224/0401; H01L 2224/16227; H01L 2224/32225; H01L 2224/32245; H01L 2224/73204; H01L 2224/81815

(57) ABSTRACT

An interposer module includes an interposer, a semiconductor die on the interposer, wherein the semiconductor die includes an equipotential pad and a passivation layer on the equipotential pad, and a plurality of connection structures connecting the equipotential pad to the interposer, wherein the passivation layer is on the equipotential pad between the plurality of connection structures.

### BACKGROUND

An equipotential pad may include a conductive surface or electrode designed to maintain a consistent electrical potential or voltage across a specific area. Equipotential pads may be used in various applications where it is desired to ensure that there is no potential difference between different points on the surface.

In operation, the equipotential pad may create a pathway for electrical charges to distribute evenly across the surface to which they are applied. This even distribution of electrical potential may help to ensure that the electrical potential is the same at all points in contact with the equipotential pad, reducing a risk of electric shock or discomfort caused by potential differences.

The equipotential pad may be made of metal or other conductive materials. The equipotential pad may come in various shapes and sizes depending on the specific application. The equipotential pad may play an important role in maintaining a uniform electrical field across a structure to provide accurate measurements or safe operation.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of an interposer module according to one or more embodiments.

FIG. 1B is a plan view (e.g., top-down view) of the interposer module according to one or more embodiments.

FIG. 1C is a detailed vertical cross-sectional view of the interposer module according to one or more embodiments.

FIG. 2A is a plan view (top down view) of the equipotential pad and TSVs according to one or more embodiments.

FIG. 2B is a perspective view of the equipotential pad and TSVs having an alternative design according to one or more embodiments.

FIG. 2C is a perspective view of the equipotential pad and TSVs having an alternative design according to one or more embodiments.

FIG. 3A is a vertical cross-sectional view of an intermediate structure including the equipotential pad according to one or more embodiments.

FIG. 3B is a vertical cross-sectional view of an intermediate structure including the passivation layer on the equipotential pad according to one or more embodiments.

FIG. 3C is a vertical cross-sectional view of an intermediate structure including the metal pillars according to one or more embodiments.

FIG. 4A is a vertical cross-sectional view of an intermediate structure including a portion of the interposer (e.g., organic interposer) on a second carrier substrate (e.g., carrier wafer) according to one or more embodiments.

FIG. 4B is a vertical cross-sectional view of an intermediate structure including the semiconductor dies on the interposer, according to one or more embodiments.

FIG. 4C is a vertical cross-sectional view of an intermediate structure including the interposer module underfill layer according to one or more embodiments.

FIG. 4D is a vertical cross-sectional view of an intermediate structure including the molding material layer, according to one or more embodiments.

FIG. 4E illustrates a vertical cross-sectional view of an intermediate structure including the plurality of C4 bumps, according to one or more embodiments.

FIG. 5 is a flow chart illustrating a method of making the interposer module according to one or more embodiments.

FIG. 6 is a vertical cross-sectional view of a package structure including the interposer module according to one more embodiments.

FIGS. 7A-7G illustrate various intermediate structures in a method of forming the package structure according to one or more embodiments.

FIG. 8 is a detailed vertical cross-sectional view of the interposer module having a first alternative design according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within the same thickness range.

An equipotential pad circuit may be used to accommodate high electrical current density. The circuit equipotential pad may utilize uni-pitch microbumps instead of other hybrid pitch microbumps which may be challenged by bump height between small pitch bumps and large pitch bumps.

A method of making the equipotential pad circuit may include forming a backside redistribution layer (backside RDL or BRDL) on a wafer (e.g., system on chip (SOC) wafer) including one or more through silicon vias (TSVs). One or more metal pillars may then be formed on the wafer (e.g., on the backside RDL). The wafer may then be separated into a plurality of dies.

One or more metal bumps may then be formed on a bottom wafer. One or more of the dies may then be attached to the bottom wafer by forming a solder joint (e.g., SOC chip joint) between the metal pillars on the dies and the metal bumps on the bottom wafer.

In the formation of equipotential pad circuits, one may experience several problems. In particular, solder wetting may be encountered due to the continuous metal layer of the equipotential pad circuit and induced solder bridging in fine-pitch zones.

One or more embodiments of the present disclosure may include an interposer module including a passivation layer (surface passivation layer) that may help to inhibit (e.g., prevent) solder bridging on an equipotential pad circuit. The passivation layer may avoid increasing a total thickness of a package structure (package). The interposer module including the passivation layer may be especially useful in portable applications and wearable applications.

A method of making the interposer module may include forming an equipotential pad on a wafer including one or more TSVs. The equipotential pad may be included in a backside RDL on a backside of the wafer. A passivation layer may then be formed on a surface of the equipotential pad. The passivation layer may have a thickness of less than about 1 μm. In at least one embodiment, the passivation layer may have a thickness in a range of 10 nm to 1000 nm, although thicker or thinner passivation layers may be used.

A photomask layer (PM layer structure) may be formed on the passivation layer. The photomask layer may include one or more openings. The passivation layer may be etched through the openings to expose the surface of the equipotential pad. One or more metal pillars may then be formed on the surface of the equipotential pad through the openings in the photomask layer. The wafer may then be diced and singulated into a plurality of dies.

One or more metal bumps may be formed on a bottom wafer (e.g., an interposer). One or more of the dies may then be attached to the bottom wafer by forming a solder joint (e.g., SOC chip joint) between the metal pillars on the dies and the metal bumps on the bottom wafer (e.g., a chip on wafer (COW) process).

The passivation layer may be formed on a copper surface (e.g., a copper surface of the equipotential pad). The passivation layer may be formed, for example, by a coating process. The passivation layer coating may also help to provide a 40-50% shear stress improvement between the copper surface and an underfill layer (UF) between the die and the bottom wafer. The passivation layer may be thermally stable and reliable. An interface between the passivation layer and the copper surface may also be highly robust.

The interposer module may include several novel aspects. In particular, the interposer module may provide a novel structure to prevent solder bridging on an equipotential pad (e.g., equipotential pad circuit) without increasing a total thickness of the interposer module for portable applications and wearable applications.

The interposer module may also include several advantages and benefits. In particular, the interposer module may provide a good joint yield for a microbump joint (e.g., CoW microbump joint). The interposer module may also help to overcome the height control challenge between small pitch bumps and large pitch bumps. The interposer module may also provide a highly competitive product and may be highly compatibility with current baseline process flow.

The interposer module may include, for example, an electrostatic discharge (ESD) protection module. In such an embodiment, one or more dies in the interposer module may include an ESD protection circuit in the FEOL region of the dies. The ESD protection circuit may include, for example, one or more ESD clamping diodes. The ESD protection circuit may be electrically coupled to the equipotential pad by the one more TSVs in the dies.

In at least one embodiment, the ESD protection module may be included in wearable devices (and/or portable device). In such an embodiment, a size and performance of the clamping diodes may be optimized for a wearable application. Wearable devices may often be in contact with the human body and, therefore, may be frequently subjected to ESD. For example, the ESD protection module may be included in smart watches, smart glasses, smart bracelets, smart necklaces, wearable medical products, and other wearable devices.

In at least one embodiment, the ESD protection module may have 3.3 V or 5.0 V maximum operating voltage and provide ESD protection up to ±30 kV and 8.2 A. The ESD protection module may include bidirectional clamping diodes housed in an ultra-compact package. In particular, the ESD protection module may be used to protect a touch panel human-machine interface (HMI), display and camera module interfaces, RF and NFC antenna, physical keys (e.g., volume key, lock key, menu key, etc.), and user interfaces (e.g., headphone jack, USB interface, SIM card, TF card, etc.). The ESD protection module may also be in other ESD-sensitive applications such as HDMI, display port, high-speed video input/output (I/O), USB I/O, industrial I/O, etc.

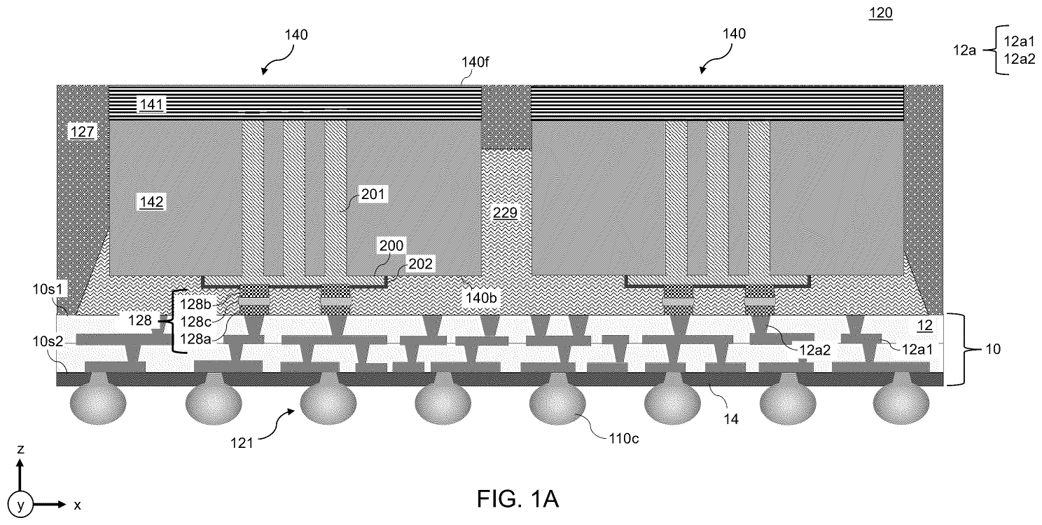

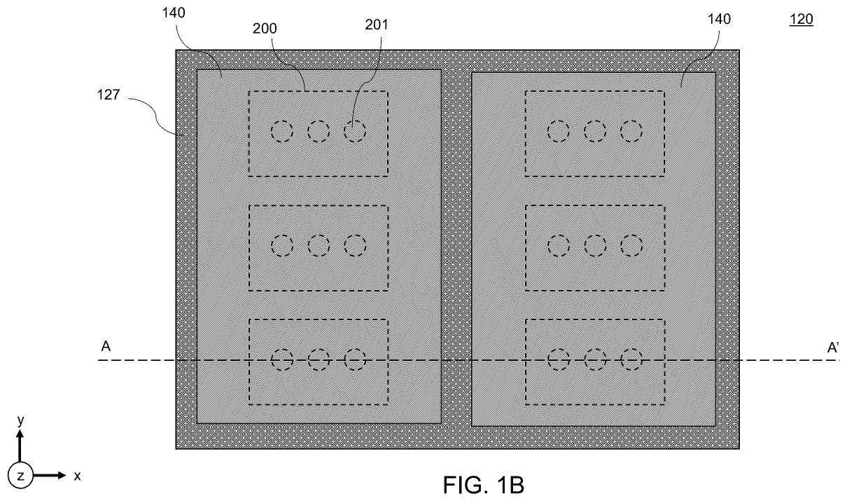

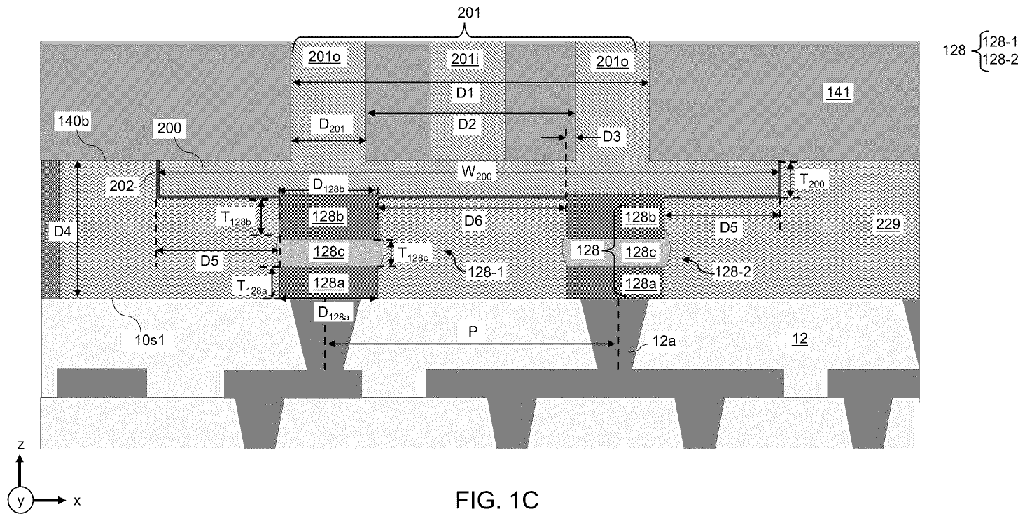

FIG. 1A is a vertical cross-sectional view of an interposer module 120 according to one or more embodiments. FIG. 1B is a plan view (e.g., top-down view) of the interposer module 120 according to one or more embodiments. The vertical cross-sectional view in FIG. 1A is along the line A-A′ in FIG. 1B. FIG. 1C is a detailed vertical cross-sectional view of the interposer module 120 according to one or more embodiments. In at least one embodiment, the interposer module 120 may include the ESD protection module described above. The interposer module 120 may be included, for example, in wearable devices such as smart watches, smart glasses, smart bracelets, smart necklaces, wearable medical products, and other wearable devices.

As illustrated in FIG. 1A, the interposer module 120 may include one or more semiconductor dies 140 on an interposer 10. Although the interposer module 120 is illustrated as including a particular number of semiconductor dies having a particular arrangement, the number of semiconductor dies and the arrangement of the semiconductor dies is not limited to any particular number and arrangement. More or fewer than the two semiconductor dies 140 illustrated in FIG. 1A may be used. In particular, the interposer module 120 may include any number and arrangement of semiconductor dies.

The interposer 10 is not necessarily limited to any particular materials or configuration. The interposer 10 may include, for example, organic material (e.g., dielectric polymer), inorganic material (e.g., silicon), glass substrate, etc. In at least one embodiment, as illustrated in FIG. 1A, the interposer 10 may include a plurality of dielectric layers 12 and a plurality of redistribution layers 12a stacked alternately. The number of the dielectric layers 12 and/or the number of redistribution layers 12a in the interposer 10 are not limited by the disclosure. In at least one embodiment, the dielectric layers 12 may include, for example, polyimide (PI), epoxy resin, acrylic resin, phenol resin, benzocyclobutene (BCB), polybenzoxazole (PBO), or any other suitable polymer-based dielectric material. A thickness of the dielectric layers 12 may be in a range from 4 μm to 60 μm. Other thicknesses of the dielectric layers 12 may be within the contemplated scope of disclosure.

The redistribution layers 12a may include conductive materials. The conductive materials may include, for example, one or more layers and may include metals, metal alloys, and/or other metal-containing compounds (e.g., Cu, Al, Ni, Mo, Co, Ru, Ti, Ta, W, TiN, TaN, WN, etc.). Other suitable metal materials are within the contemplated scope of disclosure.

The redistribution layers 12a may include metallic connection structures, i.e., metallic structures that provide electrical connection between nodes in the structure. The redistribution layers 12a may include a metallic seed layer (not shown) and a metallic fill material (not shown) on the metallic seed layer. The metallic seed layer may include, for example, a stack of a titanium barrier layer and a copper seed layer. The titanium barrier layer may have thickness in a range from 50 nm to 500 nm, and the copper seed layer may have a thickness in a range from 50 nm to 500 nm, although lesser or greater thicknesses may also be used. The metallic fill material for the redistribution layers 12a may include copper, nickel, or copper and nickel. Other suitable metallic fill materials are within the contemplated scope of disclosure. The thickness of the metallic fill material that is deposited for each redistribution layers 12a may be in a range from 2 μm to 40 μm, such as from 4 μm to 10 μm, although lesser or greater thicknesses may also be used.

In at least one embodiment, the redistribution layers 12a may include a plurality of traces 12al (lines) and a plurality of vias 12a2 connecting the plurality traces 12al to each other. The traces 12al may be respectively located on the dielectric layers 12, and may extend in the x-direction (first horizontal direction) and y-direction (second horizontal direction) on an upper surface of the dielectric layers 12.

An upper passivation layer (not shown) may optionally be formed on the chip-side surface 10s1 of the interposer 10. The upper passivation layer may include silicon oxide, silicon nitride, low-k dielectric materials such as carbon-doped oxides, extremely low-k dielectric materials such as porous carbon doped silicon dioxide, a combination thereof or other suitable material.

The semiconductor dies 140 may be connected to the interposer 10 by one or more connection structures 128. In at least one embodiment, each of the connection structures 128 may include a metal bump 128a, a metal pillar 128b and a solder joint 128c connecting the metal pillar 128b to the metal bump 128a.

One or more of the metal bumps 128a may be attached to the chip-side surface 10s1 of the interposer 10. The metal bumps 128a may be formed in the upper passivation layer (if present) on the chip-side surface of interposer 10. The upper passivation layer (if present) may at least partially cover the metal bumps 128a. That is, the metal bumps 128a may be at least partially exposed on the chip-side surface 10s1 of the interposer 10.

The metal bumps 128a may be connected to the redistribution layers 12a. In at least one embodiment, the metal bumps 128a may be formed on an upper surface of a via 12a2 in the uppermost dielectric layer 12 of the interposer 10. The metal bumps 128a may include, for example, one or more layers and may include metals, metal alloys, and/or other metal-containing compounds (e.g., Cu, Al, Ni, Mo, Co, Ru, Ti, Ta, W, TiN, TaN, WN, etc.). Other suitable metal materials are within the contemplated scope of disclosure.

The metal pillar 128b may be attached to the semiconductor die 140. The metal pillar 128b may be formed of substantially the same material as the metal bumps 128a. The metal pillar 128b may include, for example, one or more layers and may include metals, metal alloys, and/or other metal-containing compounds (e.g., Cu, Al, Ni, Mo, Co, Ru, Ti, Ta, W, TiN, TaN, WN, etc.). Other suitable metal materials are within the contemplated scope of disclosure.

The solder joint 128c may include a solder material including one or more of tin, copper, silver, bismuth, indium, zinc, and antimony. In particular, the solder material may include a tin-silver-copper alloy including about 3-4% silver, 0.5-0.7% copper, and the balance (95% or more) tin. A fourth metal such as zinc or manganese may be added to the tin-silver-copper alloy. The solder material may have a melting point in a range from 90° C. to 450° C., and more particularly, in a range from about 220° C. to 260° C.

A lower passivation layer 14 may be formed on the board-side surface 10s2 of the interposer 10. The lower passivation layer 14 may also include silicon oxide, silicon nitride, low-k dielectric materials such as carbon-doped oxides, extremely low-k dielectric materials such as porous carbon doped silicon dioxide, a combination thereof or other suitable material.

One or more interposer lower bonding pads (not shown) may be located on the board-side surface 10s2 of interposer 10. The interposer lower bonding pads may be bonded to and electrically connected to the redistribution layers 12a. The interposer lower bonding pads may be located in the lower passivation layer 14. The lower passivation layer 14 may at least partially cover the interposer lower bonding pads. That is, the interposer lower bonding pads may be at least partially exposed on the board-side surface of the interposer 10. The interposer lower bonding pads may also include, for example, one or more layers and may include metals, metal alloys, and/or other metal-containing compounds (e.g., Cu, Al, Ni, Mo, Co, Ru, Ti, Ta, W, TiN, TaN, WN, etc.). Other suitable metal materials are within the contemplated scope of disclosure.

In at least one embodiment, one or more integrated passive devices (IPDs) may optionally be located on the board-side surface 10s2 of interposer 10. The IPDs (not shown) may be bonded to and electrically connected to the redistribution layers 12a. The IPDs may be located in the lower passivation layer 14. The IPDs may include an exposed portion that projects out from the lower passivation layer 14. The IPDs may include one or more electronic components such as resistors, capacitors, inductors, coils, chokes, microstriplines, impedance matching elements, baluns, etc. The IPDs may be electrically coupled to the semiconductor dies 140 through the interposer 10.

As further illustrated in FIG. 1A, one or more C4 bumps 121 may connected to the board-side surface 10s2 of the interposer 10, respectively. The C4 bumps may be connected to the redistribution layers 12a in the lowermost dielectric layer 12 of the interposer. The C4 bumps 121 may alternatively be connected to the interposer lower bonding pads (if present).

In at least one embodiment, the C4 bumps 121 may include underbump metallurgy (UBM) layers (not shown) on the interposer lower bonding pads. The C4 bumps 121 may further include a contact pad (e.g., copper/nickel contact pad) on the UBM layers and a solder bump (e.g., SnAg solder bump) on the contact pad. The C4 bumps 121 may allow the interposer module 120 to be connected to a substrate such as a package substrate.

As illustrated in FIG. 1A, the semiconductor dies 140 may be mounted on the interposer 10 such that a height of the semiconductor dies 140 is substantially the same. Generally, a thickness in the z-direction of each of the semiconductor dies 140 may be substantially the same. Thus, the upper surfaces of each of the semiconductor dies 140 may be substantially coplanar (e.g., formed in the same x-y plane).

The semiconductor dies 140 may include backside 140b facing the interposer 10 and a frontside 140f (e.g., semiconductor die upper surface) facing away from interposer 10. The semiconductor dies 140 may include a front end of line (FEOL) region 141 at the frontside 140f of the semiconductor dies 140. The semiconductor dies 140 may also include a back end of line (BEOL) region 142 (e.g., bulk silicon region) at the backside 140b of the semiconductor dies 140. The semiconductor dies 140 may be electrically coupled to the redistribution layers 12a in the interposer 10 through the connection structures 128.

An interposer module underfill layer 229 may be formed (e.g., individually or connectively) under and around each of the semiconductor dies 140. The interposer module underfill layer 229 may also be formed around the connection structures 128. The interposer module underfill layer 229 may thereby fix each of the semiconductor dies 140 to the interposer 10. The interposer module underfill layer 229 may be formed of an epoxy-based polymeric material.

The semiconductor dies 140 may each have the same type or a different type. Each of the semiconductor dies 140 may include, for example, a singular semiconductor die, a system on chip (SOC) die, or a system on integrated chips (SoIC) die, and may be implemented by chip on wafer on substrate (CoWoS) technology or integrated fan-out on substrate (INFO-oS) technology. In particular, each of the semiconductor dies 140 may include, for example, a semiconductor chip or chiplet for a high performance computing (HPC) application, an artificial intelligence (AI) application, and a 5G cellular network application, a logic die (e.g., mobile application processor, microcontroller, etc.), or a memory die (e.g., high-bandwidth memory (HBM) die, hybrid memory cube (HMC), dynamic random access memory (DRAM) die, a Wide I/O die, a M-RAM die, a R-RAM die, an inverted AND (NAND) die, static random access memory (SRAM), etc.), a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a high data rate transceiver die, a I/O interface die, an integrated passive device (IPD) die, a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc. Other dies are within the contemplated scope of this disclosure.

In at least one embodiment, at least one of the semiconductor dies 140 may include a primary die (e.g., SOC die). Another of the semiconductor dies 140 may include an ancillary die (e.g, memory/SOC die, HBM die, etc.).

In at least one embodiment, the interposer module 120 may include an ESD protection module and one or more of the semiconductor dies 140 may include an ESD protection die. The front end of line (FEOL) region 141 of the ESD protection die may include an ESD protection circuit including one or more clamping diodes.

The semiconductor dies 140 may also include an equipotential pad 200 on the backside 140b of the semiconductor dies 140. The equipotential pad 200 may be included in a backside RDL structure located on the backside 140b of the semiconductor dies 140. A passivation layer 202 (surface passivation layer) may be located on a surface of the equipotential pad 200. The connection structures 128 may contact the surface of the equipotential pad 200 through openings in the passivation layer 202. The equipotential pad 200 may be electrically coupled to the front end of line (FEOL) region 141 of the semiconductor dies 140 by one or more TSVs 201. In the case where the front end of line (FEOL) region 141 includes the ESD protection circuit, the ESD protection circuit may be electrically coupled to the equipotential pad 200 by the one or more of the TSVs 201.

The equipotential pad 200 may be formed of a conductive material such as a metal material. In at least one embodiment, the equipotential pad 200 may include one or more layers and may include metals, metal alloys, and/or other metal-containing compounds (e.g., Cu, Al, Ni, Mo, Co, Ru, Ti, Ta, W, TiN, TaN, WN, etc.). Other suitable metal materials are within the contemplated scope of disclosure.

The TSVs 201 may also be formed of a conductive material such as a metal material. In at least one embodiment, the TSVs 201 may be formed of the same material as the equipotential pad 200. In at least one embodiment, the TSVs 201 may include one or more layers and may include metals, metal alloys, and/or other metal-containing compounds (e.g., Cu, Al, Ni, Mo, Co, Ru, Ti, Ta, W, TiN, TaN, WN, etc.). Other suitable metal materials are within the contemplated scope of disclosure.

As illustrated in FIG. 1A, in each of the semiconductor dies 140, the passivation layer 202 may be formed on the equipotential pad 200 between the connection structures 128. The passivation layer 202 may have a thickness of less than about 1 μm. In at least one embodiment, the passivation layer 202 may have a thickness in a range of 10 nm to 1000 nm. The passivation layer 202 may, therefore, avoid increasing a total thickness of an interposer module 120. The passivation layer 202 may be formed, for example, of Al₂O₃, SiO₂ and Si₃N₄. In at least embodiment, an organic self-assembled monolayer (SAM) may be used in the passivation layer 202 in advanced packaging due to its highly selective growth and relatively lower growth temperature.

In operation, in embodiments in which solder material from the solder joint 128c escapes from between the metal bump 128a and metal pillar 128b during a solder reflow process, then the passivation layer 202 may electrically insulate the equipotential pad 200 from the escaped solder material. The passivation layer 202 may, therefore, help to inhibit solder bridging on the equipotential pad 200.

The interposer module 120 may also include a molding material layer 127 formed around the semiconductor dies 140. The molding material layer 127 may also be formed on and around the interposer module underfill layer 229. The molding material layer 127 may have an outer sidewall that is substantially aligned with the outer sidewall of the interposer 10.

In at least one embodiment, the molding material layer 127 may be formed on sidewalls (inner sidewall and outer sidewall) of each of the semiconductor dies 140. The molding material layer 127 may be formed between and bonded to the sidewalls of each of the semiconductor dies 140. The molding material layer 127 may also be bonded to the chip-side surface of the interposer 10 and the interposer module underfill layer 229.

As illustrated in FIG. 1A, the molding material layer 127 may be subjected to a chemical mechanical polishing (CMP) step to form a top surface that is co-planar with the semiconductor dies 140. After polishing, the molding material layer 127 may include an upper surface that is substantially uniform (e.g., flat). The upper surface of the molding material layer 127 may alternatively or additionally include a recessed portion (not shown) that is recessed in the z-direction from the upper surface of the semiconductor dies 140.

In at least one embodiment, the molding material layer 127 may be formed of a curable material that may cure to form a hard, solid structure. The molding material layer 127 may include, for example, epoxy molding compound (EMC). In at least one embodiment, the molding material layer 127 may include a material that is substantially similar to the interposer module underfill layer 229. In at least one embodiment, the molding material layer 127 may include a polymeric material and in particular, an epoxy-based polymeric material. Other suitable molding materials may be within the contemplated scope of disclosure.

In at least one embodiment, the molding material layer 127 may have a coefficient of thermal expansion (CTE) that is substantially similar to a CTE of the interposer 10. In at least one embodiment, the molding material layer 127 may include an added material (e.g., filler material) for improving a property of the molding material layer 127 (e.g., thermal conductivity, CTE, etc.). The added material may include, for example, metal powder, metal oxide powder, etc. Other materials in the molding material layer 127 are within the contemplated scope of the disclosure.

As illustrated in FIG. 1B, shading and dashed lines are used to indicate a location of the equipotential pads 200 and the TSVs 201 on the equipotential pads 200. As illustrated in FIG. 1B, the semiconductor dies 140 may include three (3) equipotential pads 200. Fewer or greater numbers of equipotential pads 200 are within the contemplated scope of disclosure. The equipotential pads 200 may have substantially the same size and shape. The equipotential pads 200 may also be substantially aligned in the y-direction. The TSVs 201 connecting the equipotential pads 200 to the front end of line (FEOL) region 141 of the semiconductor dies 140 (see FIG. 1A) may also have the same size and shape and may also be substantially aligned in the y-direction.

The equipotential pads 200 may have a substantially rectangular shape and may be arranged longitudinally in the x-direction. Other shapes and arrangements of the equipotential pads 200 are within the contemplated scope of disclosure. As illustrated in FIG. 1B, the TSVs 201 may have a substantially circular cross-section. The TSVs 201 may be substantially aligned on their respective equipotential pad 200 in the x-direction. The TSVs 201 may also be substantially aligned in the x-direction between the semiconductor dies 140. Other shapes and arrangements of the TSVs 201 are within the contemplated scope of disclosure.

The number of equipotential pads 200 in the semiconductor dies 140 may vary between the semiconductor dies 140. That is, some of the semiconductor dies 140 may have three (3) equipotential pads 200, other semiconductor dies 140 may have two (2) equipotential pads 200, etc. The size and shape of equipotential pads 200 may vary between the semiconductor dies 140.

The number of TSVs 201 in the semiconductor dies 140 may also vary between the semiconductor dies 140. That is, some of the semiconductor dies 140 may have three (3) TSVs 201 for every equipotential pad 200, other semiconductor dies 140 may have two (2) TSVs 201 for every equipotential pads 200, etc. The size and shape of TSVs 201 may also vary between the semiconductor dies 140.

As further illustrated in FIG. 1B, the molding material layer 127 may be formed around an entire periphery of each of the semiconductor dies 140. A width of the molding material layer 127 around the periphery of the interposer module 120 may be substantially uniform. A width of the molding material layer 127 between the semiconductor dies 140 may be greater than the width of the molding material layer 127 around the periphery of the interposer module 120.

FIG. 1C is a detailed vertical cross-sectional view of a portion of the interposer module 120 according to one or more embodiments. In particular, FIG. 1C illustrates the equipotential pad 200 and the passivation layer 202 on the equipotential pad 200. FIG. 1C also illustrates the connection structures 128 that are connected to the equipotential pad 200.

As illustrated in FIG. 1C, the TSVs 201 may have a substantially rectangular vertical cross-section. The vertical cross-sectional shape of the TSVs 201 may alternatively be substantially trapezoidal and decreasing in width in a z-direction away from the equipotential pad 200. Other vertical cross-sectional shapes of the TSVs 201 are within the contemplated scope of disclosure.

The TSVs 201 may have a diameter D₂₀₁ in a range from 5 μm to 40 μm. The TSVs 201 may include a pair of outer TSVs 201o and an inner TSV 201i located between the outer TSVs 201o. The outer sidewalls of the outer TSVs 201o may be separated by a distance D1 in a range from 50 μm to 500 μm. Inner sidewalls of the outer TSVs 201o may be separated by a distance D2 in a range from 20 μm to 400 μm. The inner sidewalls of the outer TSVs 201o may be separated from an inner sidewall of the metal pillar 128c by a distance D3 in a range from 1 μm to 20 μm.

The equipotential pad 200 may have a width W₂₀₀ in the x-direction greater than the distance D1 between the outer sidewalls of the outer TSVs 201o. The width W₂₀₀ may be substantially uniform over the entire area of the equipotential pad 200. In at least one embodiment, the width W₂₀₀ may be in a range from 100 μm to 1000 μm. The equipotential pad 200 may have a thickness T₂₀₀ in a range from 5 μm to 40 μm.

The thickness of the passivation layer 202 may be less than the thickness T₂₀₀ of the equipotential pad 200. In at least one embodiment, the thickness of the passivation layer 202 may be less than 20% of the thickness T₂₀₀ of the equipotential pad 200. The thickness of the passivation layer 202 may be substantially uniform over the entire area of the passivation layer 202. The passivation layer 202 may be continuously formed over a sidewall of the equipotential pad 200 and a bottom surface of the equipotential pad 200.

The backside surface 140b of the semiconductor die 140 may be separated from the chip-side surface 10s1 of the interposer 10 by a distance D4 in a range from 10 μm to 150 μm. The thickness T₂₀₀ of the equipotential pad 200 may be less than 30% of the distance D4. The equipotential pad 200 may extend in an x-direction (e.g., laterally) beyond an outer sidewall of the connection structure 128 (e.g., an outer sidewall of the metal pillar 128b) by a distance D5 in a range from 5 μm to 100 μm. The inner sidewalls of the connection structures 128 (e.g., inner sidewalls of the metal pillars 128b) may be separated by a distance D6 in a range from 5 μm to 150 μm. The distance D6 between the inner sidewalls of the connection structures 128 may be less than the distance D2 between the inner sidewalls of the outer TSVs 201o.

The connection structures 128 may have a pitch P in a range from 10 μm to 200 μm. A pitch of the outer TSVs 201 may be substantially the same as the pitch P of the connection structures 128. In each of the connection structures 128, the metal bump 128a and the metal pillar 128b may be substantially aligned in the z-direction. The metal bump 128a may be separated in the z-direction from the metal pillar 128b by a distance equal to a thickness T_{128c} of the solder joint 128c. In at least one embodiment, the thickness T_{128c} of the solder joint 128c may be less than the thickness T_{128b} of the metal pillar 128b. In at least one embodiment, the thickness T_{128c} of the solder joint 128c may be in a range from 1 μm to 30 μm.

The metal bump 128a may have a diameter D₁₂₈ₐ in a range from 2 μm to 50 μm and a thickness T₁₂₈ₐ in a range from 5 μm to 40 μm. The metal pillar 128b may have a diameter D_{128b} in a range from 2 μm to 50 μm and a thickness T₁₂₈b in a range from 5 μm to 40 μm. In at least one embodiment the diameter D_{128b} of the metal pillar 128b may be greater than the diameter D₂₀₁ of the TSVs 201. In at least one embodiment, the thickness T₁₂₈ₐ and the thickness T_{128b} may be substantially the same and the diameter D₁₂₈ₐ and diameter D_{128b} may be substantially the same. In at least one embodiment, the thickness T₁₂₈ₐ may be less than the thickness T_{128b}.

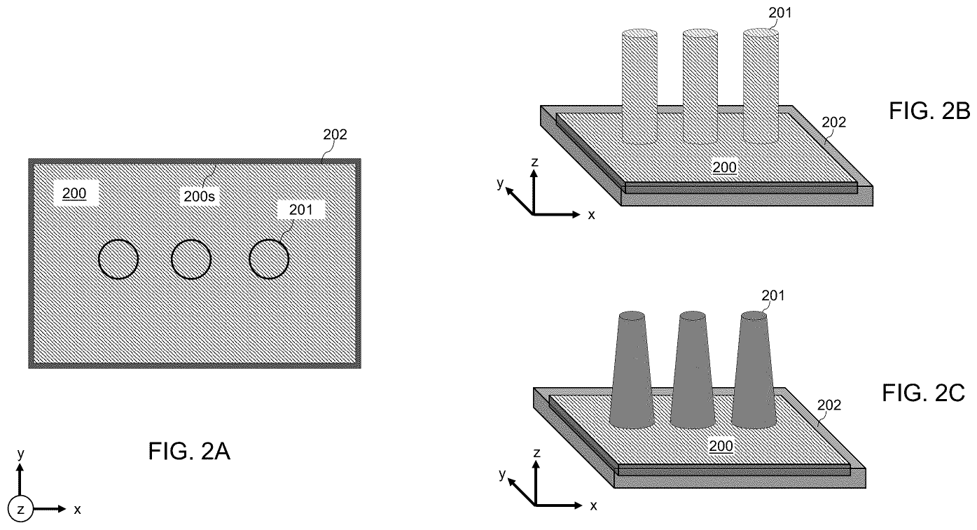

FIG. 2A is a plan view (top down view) of the equipotential pad 200 and TSVs 201 according to one or more embodiments. FIG. 2B is a perspective view of the equipotential pad 200 and TSVs 201 having an alternative design according to one or more embodiments. FIG. 2C is a perspective view of the equipotential pad 200 and TSVs 201 having an alternative design according to one or more embodiments.

As illustrated in FIG. 2A, the equipotential pad 200 may have a sidewall 200s around an entire periphery of the equipotential pad 200. The passivation layer 202 may be continuously and conformally formed around an entirety of the sidewall 200s. A thickness of the passivation layer 202 may be substantially uniform over the entirety of the sidewall 200s.

The TSVs 201 may be located in a central region of the equipotential pad 200. On the surface of the equipotential pad 200, the TSVs 201 may occupy an area which is in a range from about 5% to 30% of the total area of the surface of the equipotential pad 200.

As illustrated in FIG. 2B, the TSVs 201 may have a substantially circular cylindrical shape. As illustrated in the alternative design of FIG. 2C, the TSVs 201 may have a truncated conical shape. Other shapes of TSVs 201 are within the contemplated scope of disclosure.

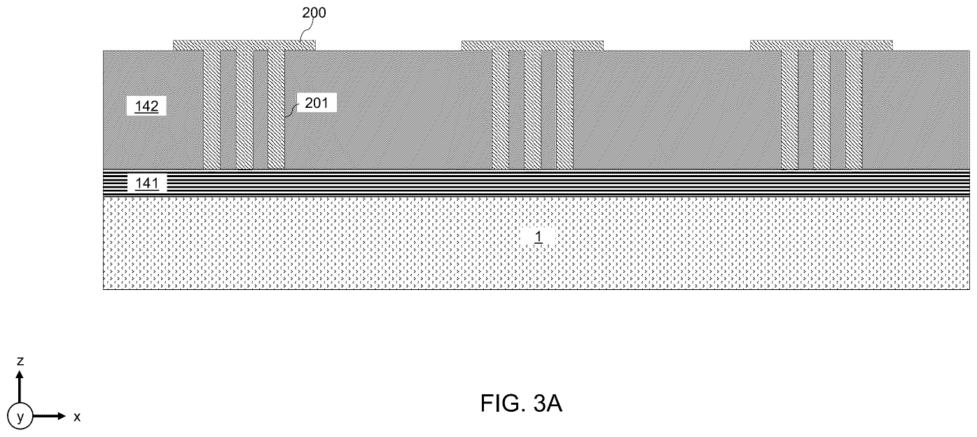

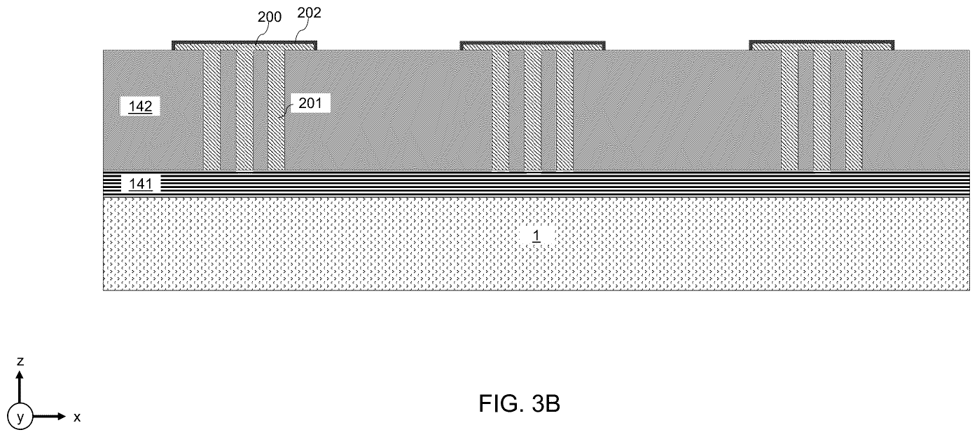

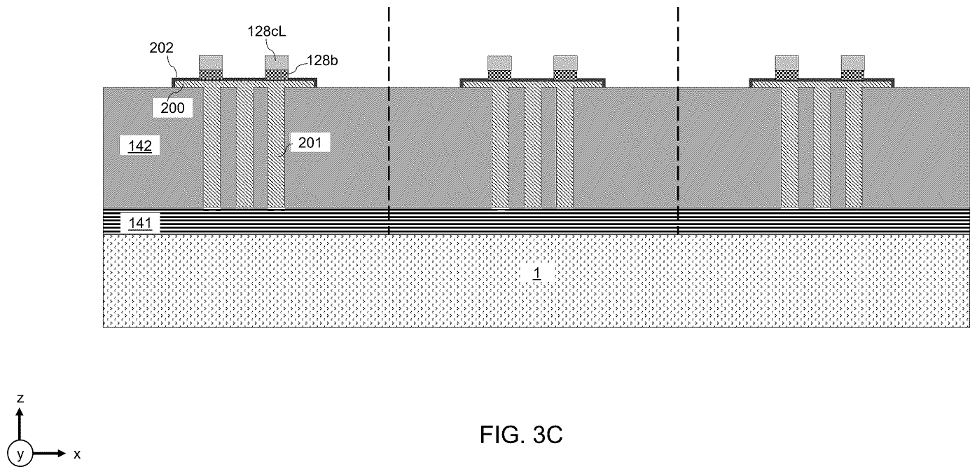

FIGS. 3A-3C are vertical cross-sectional views of intermediate structures in a forming the semiconductor dies 140 according to one more embodiments. In particular, FIG. 3A is a vertical cross-sectional view of an intermediate structure including the equipotential pad 200 according to one or more embodiments.

As illustrated in FIG. 3A, the FEOL region 141 may be formed on a first carrier substrate 1. The first carrier substrate 1 may include a circular wafer or a rectangular wafer. The lateral dimensions (such as the diameter of a circular wafer or a side of a rectangular wafer) of the first carrier substrate 1 may be in a range from 100 mm to 500 mm, such as from 200 mm to 400 mm, although lesser and greater lateral dimensions may also be used. The first carrier substrate 1 may include a semiconductor substrate, an insulating substrate, or a conductive substrate. The first carrier substrate 1 may be transparent or opaque. A thickness of the first carrier substrate 1 may be sufficient to provide mechanical support to an array of interposers to be formed thereupon. For example, the thickness of the first carrier substrate 1 may be in a range from 60 μm to 1 mm, although lesser and greater thicknesses may also be used.

An adhesive layer (not shown) may be applied to the top surface of the first carrier substrate 1. In one embodiment, the first carrier substrate 1 may include an optically transparent material such as glass or sapphire. In this embodiment, the adhesive layer may include a light-to-heat conversion (LTHC) layer. The LTHC layer is a solvent-based coating applied using a spin coating method. The LTHC layer may form a layer that converts ultraviolet light to heat such that the LTHC layer loses adhesion. Alternatively, the adhesive layer may include a thermally decomposing adhesive material. For example, the adhesive layer may include an acrylic pressure-sensitive adhesive that decomposes at an elevated temperature. The debonding temperature of the thermally decomposing adhesive material may be in a range from 150° C. to 400° C. Other suitable thermally decomposing adhesive materials that decompose at other temperatures are within the contemplated scope of disclosure.

The FEOL region 141 may be formed in a series of FEOL processing steps. The FEOL processing steps may include, for example, material deposition, photolithography, etc. The FEOL region 141 may include a plurality of individual components in one or more integrated circuits (ICs). The individual components in the FEOL region 141 may include, for example, transistors, capacitors, resistors, etc.

The BEOL region 142 may be formed on the FEOL region 141 in a series of BEOL processing steps. The BEOL region 142 may include one or more interconnection layers for interconnecting the individual components in the FEOL region 141. The interconnection layers may include one or more dielectric material layers, metal wiring (e.g., lines, traces, etc.) on the dielectric material layers, and metal vias connecting the metal wiring between the dielectric material layers. The BEOL region 142 may also include contacts and bonding sites for chip-to-package connections.

The TSVs 201 may include BEOL TSVs formed in the BEOL region 142 during the BEOL processing. The TSVs 201 may additionally or alternatively include post-BEOL TSVs formed in the BEOL region 142 (e.g., in a bulk silicon region) after the BEOL processing. The TSVs 201 may be formed as part of processing for forming a 3D packaging connection.

A process of forming of the TSVs 201 may include a photolithographic process to form via holes in the BEOL region 142. The photolithographic process may include forming a patterned photoresist mask (not shown) on the BEOL region 142, and etching (e.g., wet etching, dry etching, etc.) the exposed upper surface of the BEOL region 142 through openings in the photoresist mask. The photoresist mask may be subsequently removed by ashing, dissolving the photoresist mask or by consuming the photoresist mask during the etch process.

The equipotential pads 200 may be formed together with the TSVs 201. A metal layer may be deposited on the BEOL region 142 by CVD, PVD or other suitable deposition technique. The metal layer may be deposited both in the via holes in the BEOL region 142 and on the surface of the BEOL region 142. The metal layer may fill the via holes to form the TSVs 201. The metal layer may then be patterned by a photolithographic process. The photolithographic process may include forming a patterned photoresist mask (not shown) on the metal layer, and etching (e.g., wet etching, dry etching, etc.) the exposed upper surface of the metal material layer through openings in the photoresist mask. The photoresist mask may be subsequently removed by ashing, dissolving the photoresist mask or by consuming the photoresist mask during the etch process.

FIG. 3B is a vertical cross-sectional view of an intermediate structure including the passivation layer 202 on the equipotential pad 200 according to one or more embodiments. A layer of passivation material may be deposited on the BEOL region 142 and on the equipotential pads 200, for example, by a wet coating process. The layer of passivation material may alternatively be formed by CVD, PVD or other suitable deposition technique.

In the wet coating process, the passivation material may be added to a solvent to form a passivation material solution that is suitable for application. The passivation material solution may then be applied to the BEOL region 142 and on the equipotential pads 200 by one or more of spin coating, dip coating, spray coating, etc. The intermediate structure may then undergo a curing or drying process to remove the solvent and solidify the passivation material.

The passivation material may then be patterned by a photolithographic process. The photolithographic process may include forming a patterned photoresist mask (not shown) on the passivation material, and etching (e.g., wet etching, dry etching, etc.) the exposed upper surface of the passivation material through openings in the photoresist mask. The photoresist mask may be subsequently removed by ashing, dissolving the photoresist mask or by consuming the photoresist mask during the etch process.

FIG. 3C is a vertical cross-sectional view of an intermediate structure including the metal pillars 128b according to one or more embodiments. After the passivation layer 202 is formed on the equipotential pads 200, openings for the metal pillars 128b may be formed in the passivation layer 202. To form the openings, the passivation layer 202 may be patterned by a photolithographic process. The photolithographic process may include forming a patterned photoresist mask (not shown) on the passivation layer 202, and etching (e.g., wet etching, dry etching, etc.) the exposed upper surface of the passivation layer 202 through openings in the photoresist mask. The photoresist mask may be subsequently removed by ashing, dissolving the photoresist mask or by consuming the photoresist mask during the etch process.

The metal pillars 128b may then be formed on a surface of the equipotential pad 200 in the openings in the passivation layer 202, respectively. The metal pillars 128b may be formed, for example, by an electroplating process, a photolithographic process, or other suitable process. In the photolithographic process, a metal material layer may be deposited on the passivation layer 202 (by CVD, PVD or other suitable deposition technique) and then patterned by a photolithographic process to form the metal pillars 128b.

Solder material layers 128cL may then be formed on the metal pillars 128b, respectively. The solder material layers 128cL may eventually form the solder joints 128c in the interposer module 120. Thus, the solder material layers 128cL may include the materials described above for the solder joint 128c. The solder material layers 128cL may be formed on the metal pillars 128b by one or more processes including ball mounting, electroplating, solder printing, solder immersion and solder injection.

After the solder material layers 128cL are formed, a singulation process may be performed to separate the intermediate structure in FIG. 3C into individual semiconductor dies 140. The singulation process may include dicing the FEOL region 141 and BEOL region 142 along the dashed lines (dicing lines) in FIG. 3C.

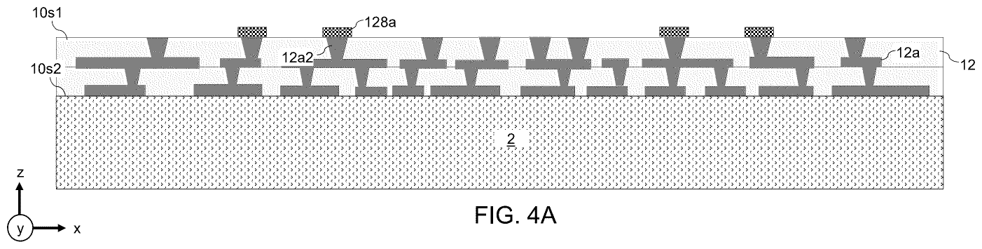

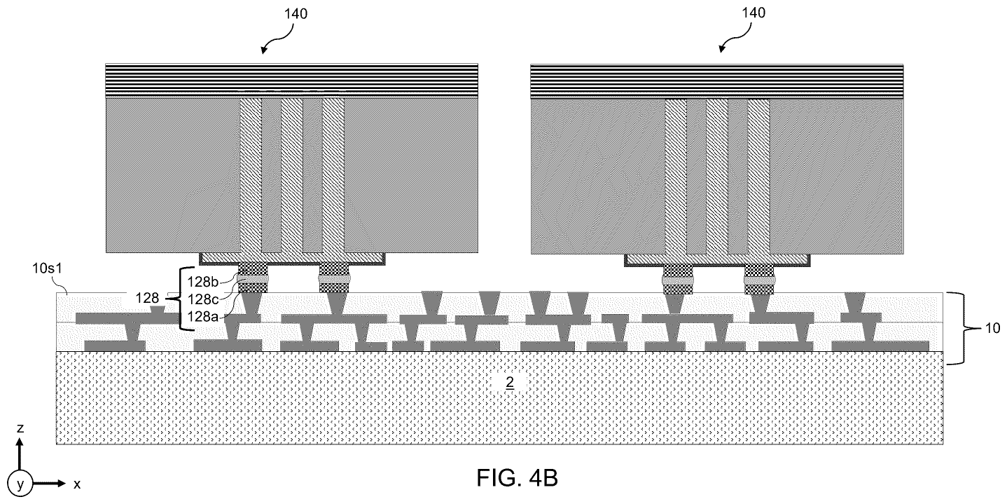

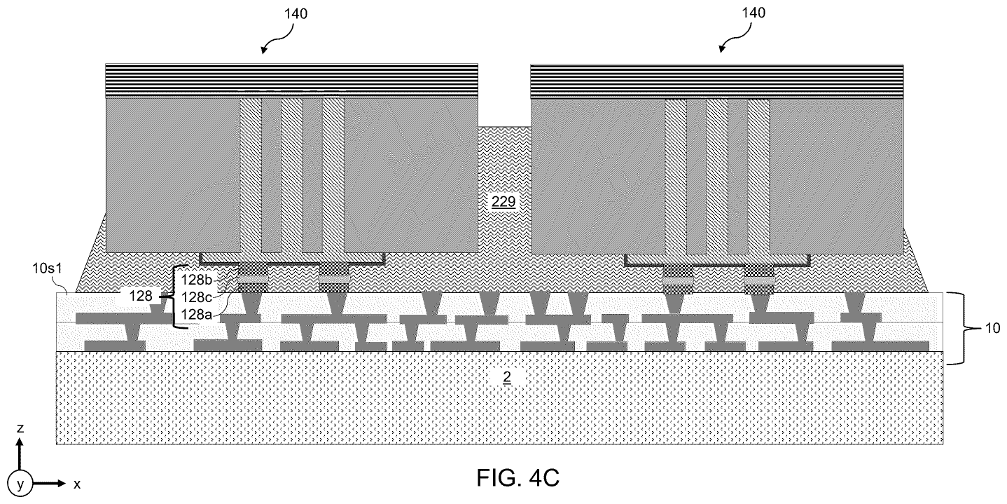

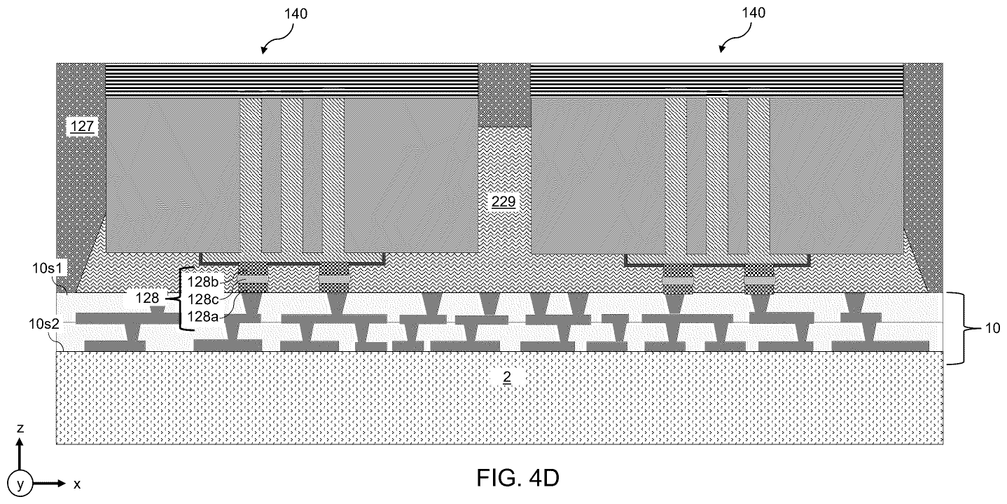

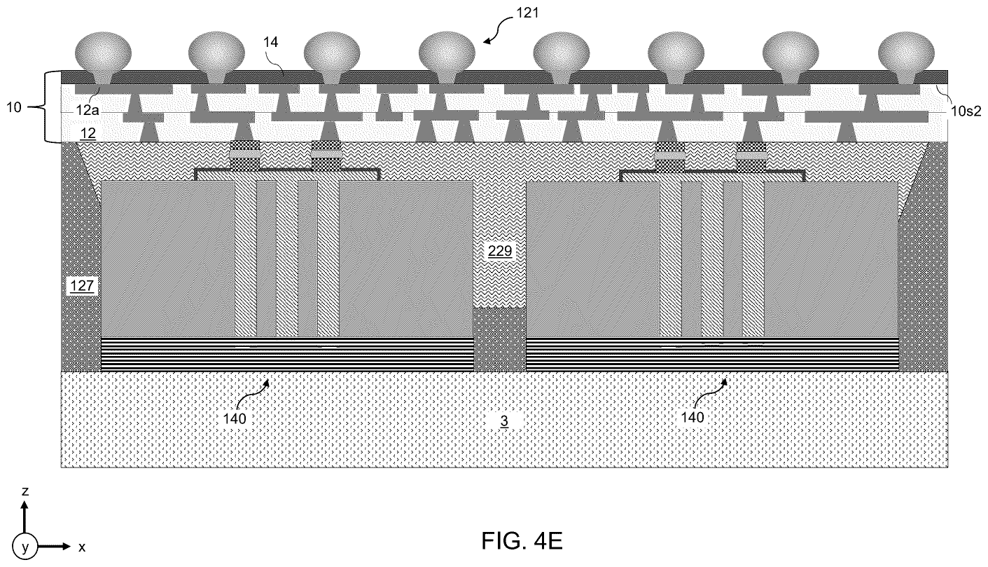

FIGS. 4A-4E are vertical cross-sectional views of intermediate structures in a method of making the semiconductor module 120 according to one more embodiments. FIG. 4A is a vertical cross-sectional view of an intermediate structure including a portion of the interposer 10 (e.g., organic interposer) on a second carrier substrate 2 (e.g., carrier wafer) according to one or more embodiments. The lower passivation layer 14 of the interposer 10 may be formed later in the method of forming the interposer module 120. The second carrier substrate 2 may be substantially the same as the first carrier substrate 1 described above.

An adhesive layer (not shown) may be applied to the top surface of the second carrier substrate 2. The adhesive layer may be substantially the same as the adhesive layer described above with respect to FIG. 3A (e.g., the adhesive layer may include a light-to-heat conversion (LTHC) layer, a thermally decomposing adhesive material, etc.).

A plurality of dielectric layers 12 and plurality of redistribution layers 12a may be alternately formed on the second carrier substrate 2 (e.g., on the adhesive layer on the second carrier substrate 2). It should be noted that although FIG. 4A illustrates two dielectric layers 12 and two redistribution layers 12a, more or fewer dielectric layers 12 and redistribution layers 12a are contemplated by the present disclosure.

Each dielectric layer 12 may each be formed, for example, by depositing (e.g., by chemical vapor deposition (CVD), physical vapor deposition (PVD) or other suitable deposition technique) a layer of dielectric polymer material such as polyimide (PI), benzocyclobutene (BCB), or polybenzobisoxazole (PBO). Other suitable materials are within the contemplated scope of disclosure. The thickness of the layer of dielectric polymer material may be in a range from 4 μm to 60 μm, although lesser and greater thicknesses may also be used. The dielectric layer 12 may then be patterned by a photolithographic process to form via holes in the dielectric layer 12. The photolithographic process may include forming a patterned photoresist mask (not shown) on the layer of dielectric material, and etching (e.g., wet etching, dry etching, etc.) the exposed upper surface of the dielectric material through openings in the photoresist mask. The photoresist mask may be subsequently removed by ashing, dissolving the photoresist mask or by consuming the photoresist mask during the etch process.

A redistribution layer 12a (e.g., metal traces and metal vias) may then be formed on the dielectric layer 12. The redistribution layer 12a may be formed, for example, by depositing (e.g., by CVD, PVD or other suitable deposition technique) one or more layers of metal material such as copper, aluminum, nickel, titanium, a combination thereof or other suitable metals, on the dielectric layer 12 and in the vias holes formed by patterning the dielectric layer 12. The layer of metal material may then be patterned by a photolithographic process to form the redistribution layer. The photolithographic process may include forming a patterned photoresist mask (not shown) on the layer of metal material, and etching (e.g., wet etching, dry etching, etc.) the exposed upper surface of the metal material through openings in the photoresist mask. The photoresist mask may be subsequently removed by ashing, dissolving the photoresist mask or by consuming the photoresist mask during the etch process.

As further illustrated in FIG. 4A, the metal bumps 128a may then be formed on the uppermost dielectric layer 12 (e.g., on the chip-side surface 10s1 of the interposer 10). Each of the metal bumps 128a may be formed in contact with a respective via 12a2 in the uppermost dielectric layer 12. The metal bumps 128a may include any metallic material that may be bonded to a solder material. The metal bumps 128a may be formed by depositing (e.g., by CVD, PVD or other suitable deposition technique) one or more metal layers including a metal, metal alloys, and/or other metal-containing compounds (e.g., Cu, Al, Ni, Mo, Co, Ru, Ti, Ta, W, TiN, TaN, WN, etc.). The metal layer may then be patterned by a photolithographic process so as to form the metal bumps 128a. The photolithographic process may include forming a patterned photoresist mask (not shown) on the metallic material, and etching (e.g., wet etching, dry etching, etc.) the exposed upper surface of the metallic material through openings in the photoresist mask. The photoresist mask may be subsequently removed by ashing, dissolving the photoresist mask or by consuming the photoresist mask during the etch process.

In at least one embodiment, the metal bumps 128a may include an underbump metallurgy (UBM) layer stack deposited on the vias 12a2. The order of material layers within the UBM layer stack may be selected such that solder material portions may be subsequently bonded to portions of the bottom surface of the UBM layer stack. Layer stacks that may be used for the UBM layer stack include, but are not limited to, stacks of Cr/Cr-Cu/Cu/Au, Cr/Cr-Cu/Cu, TiW/Cr/Cu, Ti/Ni/Au, and Cr/Cu/Au. Other suitable materials are within the contemplated scope of disclosure. The thickness of the UBM layer stack may be in a range from 5 μm to 60 μm, such as from 10 μm to 30 μm, although lesser and greater thicknesses may also be used. A photoresist layer may be applied over the UBM layer stack, and may be lithographically patterned to form an array of discrete patterned photoresist material portions. An etch process may be performed to remove unmasked portions of the UBM layer stack. The etch process may be an isotropic etch process or an anisotropic etch process. Remaining portions of the UBM layer stack may form the metal bumps 128a. In at least one embodiment, the metal bumps 128a may be arranged as a two-dimensional array, which may be a two-dimensional periodic array such as a rectangular periodic array.

FIG. 4B is a vertical cross-sectional view of an intermediate structure including the semiconductor dies 140 on the interposer 10, according to one or more embodiments. The semiconductor dies 140 may be placed on the interposer 10, for example, by using an electro-mechanical pick-and-place (PNP) machine. Each of the semiconductor dies 140 may then be bonded to the interposer 10 by one or more of the connection structures 128. In at least one embodiment, the connection structures 128 may include a two-dimensional array of connection structures 128.

Each of the semiconductor dies 140 may be attached to the metal bumps 128a by a C2 bonding process, (e.g., solder bonding). In the C2 bonding process, each of the solder layers 128cL (which are on the metal pillars 128b which are on an equipotential pad 200 of a semiconductor die 140) may be positioned over a respective metal bump 128a on the chip-side surface 10s1 of the interposer 10. The intermediate structure may then be heated to cause reflow of the solder layer 128cL onto the respective metal bump 128a and form the solder joint 128c between the metal bump 128a and the metal pillar 128b. Other methods of bonding the semiconductor dies 140 to the interposer 10 (e.g., hybrid bonding) are within the contemplated scope of disclosure.

FIG. 4C is a vertical cross-sectional view of an intermediate structure including the interposer module underfill layer 229 according to one or more embodiments. The interposer module underfill layer 229 may be applied by depositing and/or injecting an underfill material such as an epoxy-based polymeric material onto the interposer 10. The underfill material may be applied on the interposer 10 so as to be formed under the semiconductor dies 140 and around the connection structures 128. In at least one embodiment, the underfill material may fill substantially all of the gaps between the semiconductor dies 140 and the interposer 10. The underfill material may then be cured to form the interposer module underfill layer 229. The underfill material may be cured, for example, in a box oven for duration in a range from 60 minutes to 120 minutes at a temperature in a range from 120° C. to 180° C. to provide the interposer module underfill layer 229 with a sufficient stiffness and mechanical strength.

FIG. 4D is a vertical cross-sectional view of an intermediate structure including the molding material layer 127, according to one or more embodiments. The molding material layer 127 (e.g., encapsulant layer) may be formed on the semiconductor dies 140 and interposer 10. In at least one embodiment, the molding material layer 127 may be formed by a sequence of an over-molding process and a planarization process. In particular, the molding material layer 127 may include an epoxy polymer material (e.g., an epoxy molding compound (EMC)). The molding material layer 127 may be formed on the interposer 10 and fill in the gaps between the semiconductor dies 140. The molding material layer 127 may encapsulate (e.g., in the x-direction and y-direction) the semiconductor dies 140. The molding material layer 127 may be formed, for example, by a deposition process such as CVD, PECVD, PVD, spin coating, lamination or other suitable deposition technique.

The molding material layer 127 may be deposited so as to completely cover the semiconductor dies 140 and the interposer module underfill layer 229. After the molding material layer 127 has cured, a planarization process may then be used to make an upper surface of the molding material layer 127 substantially coplanar with an upper surface of the semiconductor dies 140. The planarization process may be performed on the upper surface of the molding material layer 127 until an upper surface of the semiconductor dies 140 are exposed. The planarization process may include, for example, a mechanical grinding process and/or a CMP process.

FIG. 4E illustrates a vertical cross-sectional view of an intermediate structure including the plurality of C4 bumps 121, according to one or more embodiments. After the molding material layer 127 has been cured and planarized (e.g., by grinding, CMP, etc.), the intermediate structure may be attached to a third carrier substrate 3. The third carrier substrate 3 may be substantially similar to the first carrier substrate 1 and the second carrier substrate 2. In particular, the third carrier substrate 3 may be attached to the upper surface of the molding material layer 127 and the upper surface of the semiconductor dies 140.

The intermediate structure of FIG. 4D may then be inverted and the second carrier substrate 2 may be detached from the board-side surface 10s2 of the interposer 10. The second carrier substrate 2 may be detached from the interposer 10, for example, by deactivating the adhesive layer (not shown) adhering the second carrier substrate 2 to the interposer 10. The adhesive layer may be deactivated, for example, by a thermal anneal at an elevated temperature (e.g., for a thermally-deactivated adhesive material, or by exposing the adhesive layer to ultraviolet light (e.g., for an ultraviolet-deactivated adhesive material).

The interposer lower bonding pads (if present) may then be formed on the lower dielectric layer 12 of the interposer 10. The interposer lower bonding pads may be formed using substantially the same materials and substantially the same photolithographic processes as described above for the metal bumps 128a. The lower passivation layer 14 may then be formed on the lower dielectric layer 12 of the interposer 10 and over the interposer lower bonding pads.

The lower passivation layer 14 may be formed by depositing (e.g., by CVD, PVD or other suitable deposition technique) one or more layers of passivation material including silicon oxide, silicon nitride, low-k dielectric materials such as carbon-doped oxides, extremely low-k dielectric materials such as porous carbon doped silicon dioxide, a combination thereof or other suitable material. The passivation material may then be planarized (e.g., by wet etching, drying etching, chemical mechanical polishing (CMP), etc.) so as to form the lower passivation layer 14. The lower passivation layer 14 may then be etched by a suitable etching process (e.g., by wet etching, dry etching, etc.) to form openings over the redistribution layers 12a in the lower dielectric layer 12 (or over the interposer lower bonding pads if present).

The plurality of C4 bumps 121 may then be formed on the intermediate structure. The C4 bumps 121 may include, for example, solder bumps formed in the openings in the lower passivation layer 14. The C4 bumps 121 may be formed by one or more processes including ball mounting, electroplating, solder printing, solder immersion and solder injection. The C4 bumps 121 may contact the redistribution layers 12a in the lower dielectric layer 12 of the interposer 10 (or the interposer lower bonding pads if present) through the openings in the lower passivation layer 14. In at least one embodiment, the C4 bumps 121 may be formed by forming one or more underbump metallization (UBM) layers (not shown) on the exposed surface of the redistribution layers 12a (or the exposed surface of the interposer lower bonding pads if present), forming contact pads on the UBM layers, and then forming the solder bumps on the contact pads.

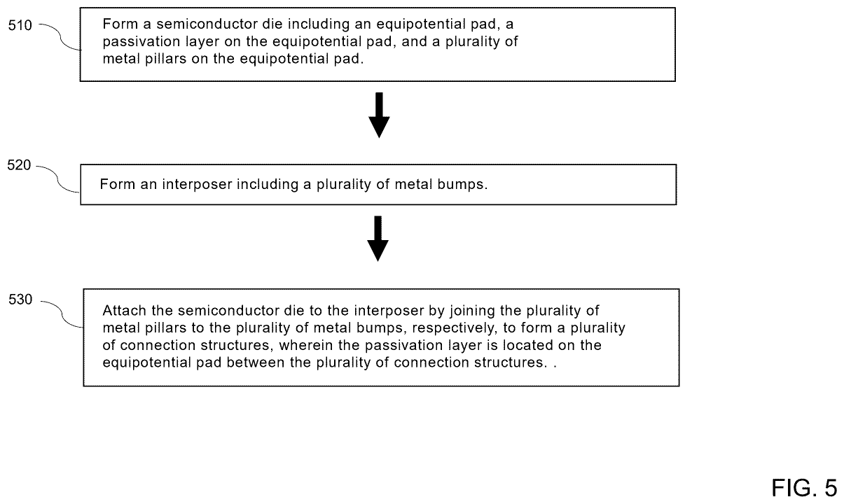

FIG. 5 is a flow chart illustrating a method of making the interposer module 120 according to one or more embodiments. Step 510 includes forming a semiconductor die including an equipotential pad, a passivation layer on the equipotential pad, and a plurality of metal pillars on the equipotential pad. Step 520 includes forming an interposer including a plurality of metal bumps. Step 530 includes attaching the semiconductor die to the interposer by joining the plurality of metal pillars to the plurality of metal bumps, respectively, to form a plurality of connection structures, wherein the passivation layer is located on the equipotential pad between the plurality of connection structures.

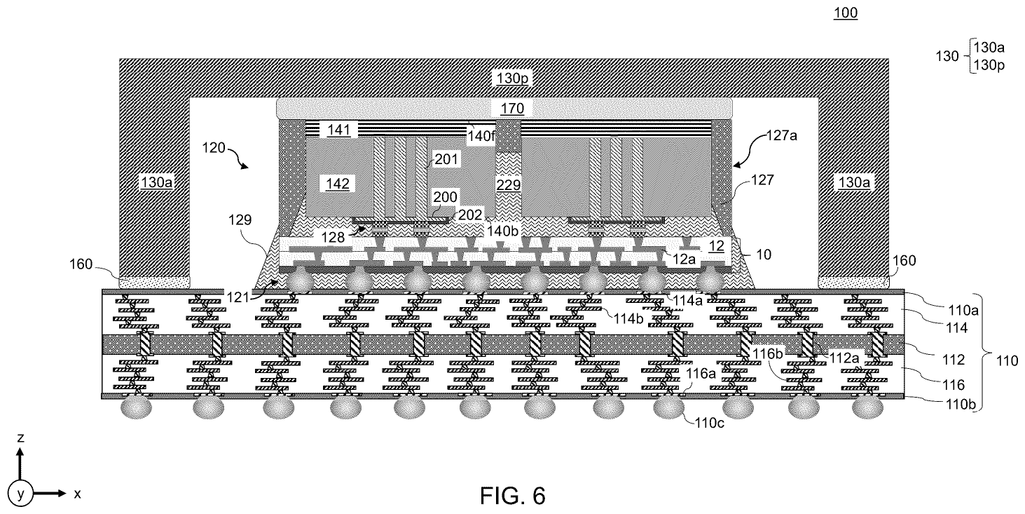

FIG. 6 is a vertical cross-sectional view of a package structure 100 including the interposer module 120 according to one more embodiment.

As illustrated in FIG. 6, the package structure 100 may include a package substrate 110 and the interposer module 120 on the package substrate 110. The package structure 100 may also include a package lid 130 on the interposer module 120. The package lid 130 may include a package lid foot portion 130a attached to the package substrate 110. The package lid 130 may also include a package lid plate portion 130p connected to the package lid foot portion 130a. The package structure 100 may also include a TIM layer 170 between the interposer module 120 and the package lid plate portion 130p.

The package substrate 110 may include a cored or coreless substrate. In at least one embodiment, for example, the package substrate 110 may include a core 112, a package substrate upper dielectric layer 114 formed on the core 112 (e.g., a first side or chip-side of the package substrate 110), and a package substrate lower dielectric layer 116 formed on the core 112 (e.g., a second side or board-side of the package substrate 110). In particular, the package substrate 110 may include a build-up film substrate such as an Ajinomoto build-up film (ABF) substrate. That is, in at least one embodiment, each of the package substrate upper dielectric layer 114 and the package substrate lower dielectric layer 116 may be described as an ABF layer.

The core 112 may help to provide rigidity to the package substrate 110. The core 112 may include, for example, an epoxy resin such as a bismaleimide triazine epoxy (BT epoxy) and/or a woven glass laminate. The core 112 may alternatively or in addition include an organic material such as a polymer material. In particular, the core 112 may include a dielectric polymer material such as polyimide (PI), benzocyclobutene (BCB) polymer, or polybenzobisoxazole (PBO). Other suitable dielectric materials are within the contemplated scope of disclosure.

The core 112 may include one or more through vias 112a. The through vias 112a may extend from a lower surface of the core 112 to an upper surface of the core 112. The through vias 112a may allow an electrical connection between the package substrate upper dielectric layer 114 and the package substrate lower dielectric layer 116. The through vias 112a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The package substrate upper dielectric layer 114 may be formed on an upper surface of the core 112. The package substrate upper dielectric layer 114 may include a plurality of layers and, in particular, may include a build-up film (e.g., ABF). The package substrate upper dielectric layer 114 may also include an organic material such as a polymer material. In particular, the package substrate upper dielectric layer 114 may include a dielectric polymer material such as polyimide (PI), benzocyclobutene (BCB), or polybenzobisoxazole (PBO). Other suitable dielectric materials are within the contemplated scope of disclosure.

The package substrate upper dielectric layer 114 may include one or more package substrate upper bonding pads 114a on a chip-side surface of the package substrate upper dielectric layer 114. The package substrate upper bonding pads 114a may be exposed on the chip-side surface of the package substrate upper dielectric layer 114. The package substrate upper dielectric layer 114 may also include one or more metal interconnect structures 114b. The metal interconnect structures 114b may electrically couple the package substrate upper bonding pads 114a to the through vias 112a in the core 112. The metal interconnect structures 114b may include metal layers (e.g., copper traces) and metal vias connecting the metal layers. The package substrate upper bonding pads 114a and the metal interconnect structures 114b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A package substrate upper passivation layer 110a may be formed on the chip-side surface of the package substrate upper dielectric layer 114. The package substrate upper passivation layer 110a may at least partially cover the package substrate upper bonding pads 114a. The upper passivation layer 110a may include silicon oxide, silicon nitride, low-k dielectric materials such as carbon-doped oxides, extremely low-k dielectric materials such as porous carbon doped silicon dioxide, a combination thereof or other suitable material.

The package substrate lower dielectric layer 116 may be formed on a lower surface of the core 112. The package substrate lower dielectric layer 116 may also include a plurality of layers and, in particular, may include a build-up film (e.g., ABF). The package substrate lower dielectric layer 116 may also include an organic material such as a polymer material. In particular, the package substrate lower dielectric layer 116 may include a dielectric polymer material such as polyimide (PI), benzocyclobutene (BCB), or polybenzobisoxazole (PBO). Other suitable dielectric materials are within the contemplated scope of disclosure.

The package substrate lower dielectric layer 116 may include one or more package substrate lower bonding pads 116a on a board-side surface of the package substrate lower dielectric layer 116. The package substrate lower dielectric layer 116 may also include one or more metal interconnect structures 116b. The metal interconnect structures 116b may electrically couple the package substrate lower bonding pads 116a to the through vias 112a in the core 112. The metal interconnect structures 116b may include metal layers (e.g., copper traces) and metal vias connecting the metal layers. The package substrate lower bonding pads 116a and the metal interconnect structures 116b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A package substrate lower passivation layer 110b may be formed on the board-side surface of the package substrate lower dielectric layer 116. The package substrate lower passivation layer 110b may at least partially cover the package substrate lower bonding pads 116a. The package substrate lower passivation layer 110b may include silicon oxide, silicon nitride, low-k dielectric materials such as carbon-doped oxides, extremely low-k dielectric materials such as porous carbon doped silicon dioxide, a combination thereof or other suitable material.

A ball-grid array (BGA) including a plurality of solder balls 110c may be formed on the board-side surface of the package substrate 110. The solder balls 110c may allow the package structure 100 to be securely mounted on a substrate such as a printed circuit board (PCB) and electrically coupled to the PCB substrate. The solder balls 110c may contact the package substrate lower bonding pads 116a, respectively. The solder balls 110c may therefore be electrically connected to the package substrate upper bonding pads 114a by way of metal interconnect structures 116b, the through vias 112a and the metal interconnect structures 114b. The solder balls 110c of the BGA may be formed in a two-dimensional array on the board-side surface of the package substrate 110. The solder balls 110c may be located, for example, under the package lid foot portion 130a and under the interposer module 120.

As illustrated in FIG. 6, the package substrate 110 may have a width in the x-direction that is greater than a width of the interposer module 120 in the x-direction. The package substrate 110 may also have a length in the y-direction that is greater than a length of the interposer module 120 in the y-direction. The interposer module 120 may be located in a central portion of the package substrate 110.

The interposer module 120 may be attached by C4 bumps 121 to the package substrate upper bonding pads 114a in the package substrate 110. The C4 bumps 121 may include a metal pillar (not shown) and a solder bump (e.g., SnAg solder bump) on the metal pillar. The solder bump may be collapsed to join the metal pillar of the C4 bump 121 to the package substrate upper bonding pads 114a.

A package underfill layer 129 may be formed on the package substrate 110 under and around the interposer module 120. The package underfill layer 129 may also be formed around the C4 bumps 121. The package underfill layer 129 may thereby securely fix the interposer module 120 to the package substrate 110. The package underfill layer 129 may be formed of an underfill material such as an epoxy-based polymeric material. Other suitable materials may be used for the package underfill layer 129.

The TIM layer 170 may be located on the interposer module 120. The TIM layer 170 may include one or more layers. In at least one embodiment, a center of the TIM layer 170 may be substantially aligned with a center of the interposer module 120. In at least one embodiment, the TIM layer 170 may extend laterally (e.g., in the x-y plane) beyond the outer sidewall 127a of the molding material layer 127.

The TIM layer 170 may have a low bulk thermal impedance and high thermal conductivity. The TIM layer 170 may cover an entire area of the upper surface of the interposer module 120. The TIM layer 170 may be attached to the upper surface of the interposer module 120 by a thermally conductive adhesive.

In at least one embodiment, the TIM layer 170 may include one or more metals. The TIM layer 170 may include, for example, a low-melting-temperature (LMT) metal TIM or liquid metal TIM. The TIM layer 170 may include one or more metals such as indium, tin, gallium, silver, etc. The TIM layer 170 may include, for example, a gallium base, indium base, silver base, solder base, etc. The solder base may include tin and one or more other elements such as copper, silver, bismuth, indium, zinc, antimony, etc.

The TIM layer 170 may alternatively or additionally include a thermal grease, a thermal paste, thermal film, thermal adhesive, thermal gap filler, thermal pad (e.g., silicone), thermal tape or a gel-type TIM (e.g., a cross-linked polymer film). In at least one embodiment, the TIM layer 170 may include graphite, carbon nanotubes (CNTs), phase-change material (PCM), etc. The PCM may include, for example, a polymer based PCM. In at least one embodiment, the PCM may change its phase from solid to high-viscosity semi liquid around 60° C. Other materials in the TIM layer 170 are within the contemplated scope of this disclosure.

As further illustrated in FIG. 6, the package lid 130 may be located on the TIM layer 170 and may provide a cover for the interposer module 120. The package lid 130 may be formed, for example, of metal, ceramic or polymer material. Other suitable materials of the package lid 130 may be used.

The package lid foot portion 130a of the package lid 130 may be attached to the package substrate 110. The package lid foot portion 130p may extend in a substantially perpendicular direction from the package lid plate portion 130p. The package lid foot portion 130p may be connected to the package substrate 110 by an adhesive layer 160. The adhesive layer 160 may include, for example, epoxy adhesive or silicone adhesive. Other adhesives are within the contemplated scope of this disclosure.

The package lid plate portion 130p (e.g., main body of the package lid 130) may be connected to the package lid foot portion 130a (e.g., an upper end of the package lid foot portion 130a). In at least one embodiment, the package lid plate portion 130p may be integrally formed as a unit with the package lid foot portion 130a. The package lid plate portion 130p may alternatively be formed separate from the package lid foot portion 130a and attached to the package lid foot portion 130a by an adhesive (not shown). The adhesive may be substantially similar to the adhesive layer 160 described above.

The package lid plate portion 130p may have a plate-shape extending, for example, in an x-y plane in FIG. 6. An outer periphery of the package lid plate portion 130p may be substantially aligned with an outer periphery of the package lid foot portion 130a. The package lid plate portion 130p may be substantially parallel to an upper surface of the package substrate 110. The package lid plate portion 130p may include a central region that is formed over the interposer module 120. In at least one embodiment, a center point (in the x-y plane) of the central region may be substantially aligned with the center point of the interposer module 120 and/or with the center point of the TIM layer 170.

The package substrate 110 may have a substantially rectangular shape having a length in the x-direction greater than the width in y-direction. The package substrate 110 may alternatively have a substantially square shape. Each of the package lid foot portion 130a and interposer module 120 may have an outer shape that is substantially the same as an outer shape of the package substrate 110. Other shapes of the package substrate 110, package lid 130 and interposer module 120 are within the contemplated scope of disclosure. The interposer module 120 may be arranged in a central portion of the package substrate 110 so that a space between the interposer module 120 and the package lid foot portion 130a is substantially uniform around the perimeter of the interposer module 120.

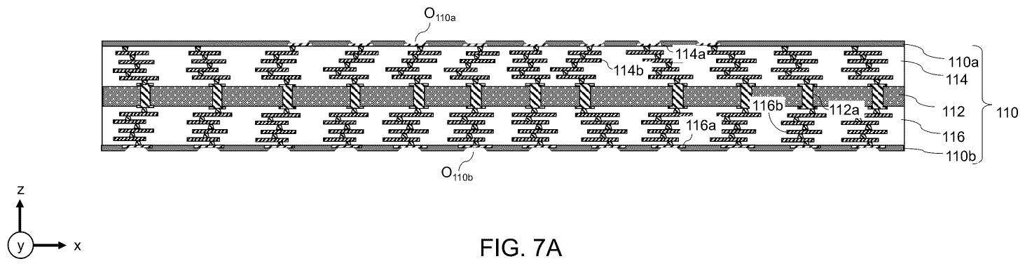

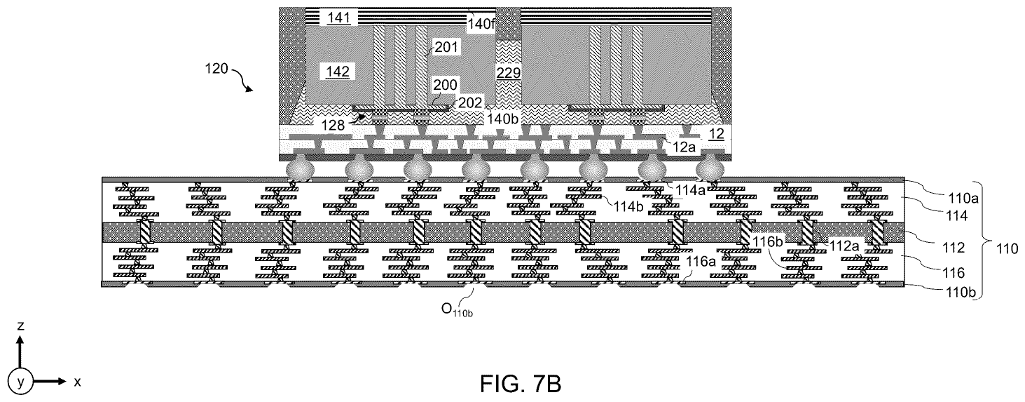

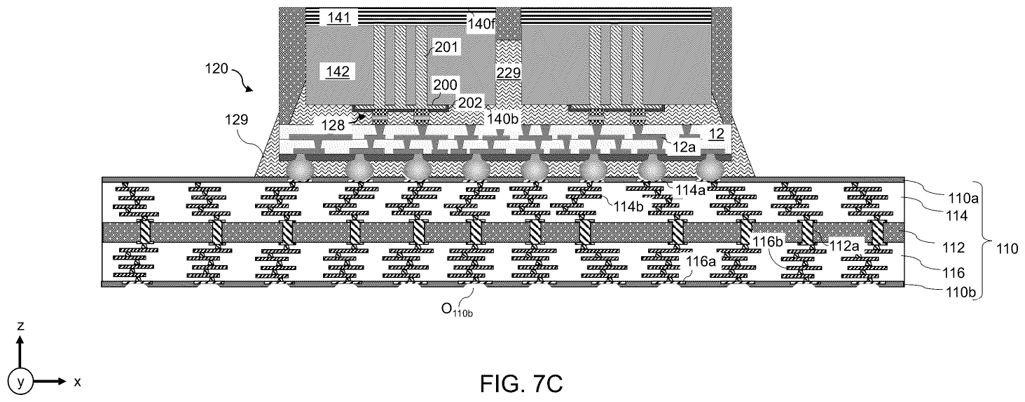

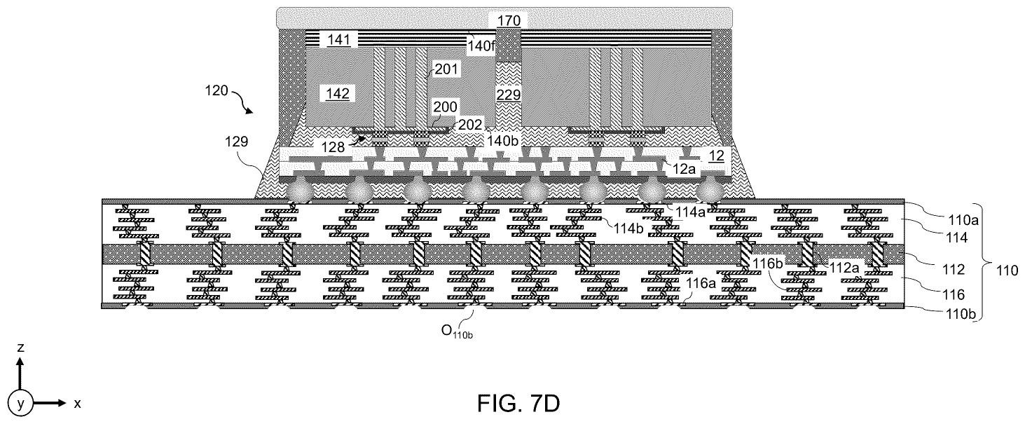

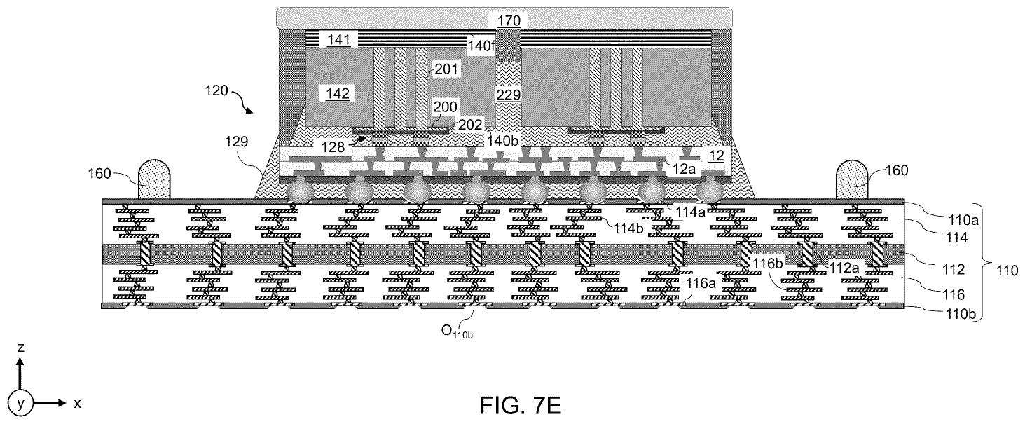

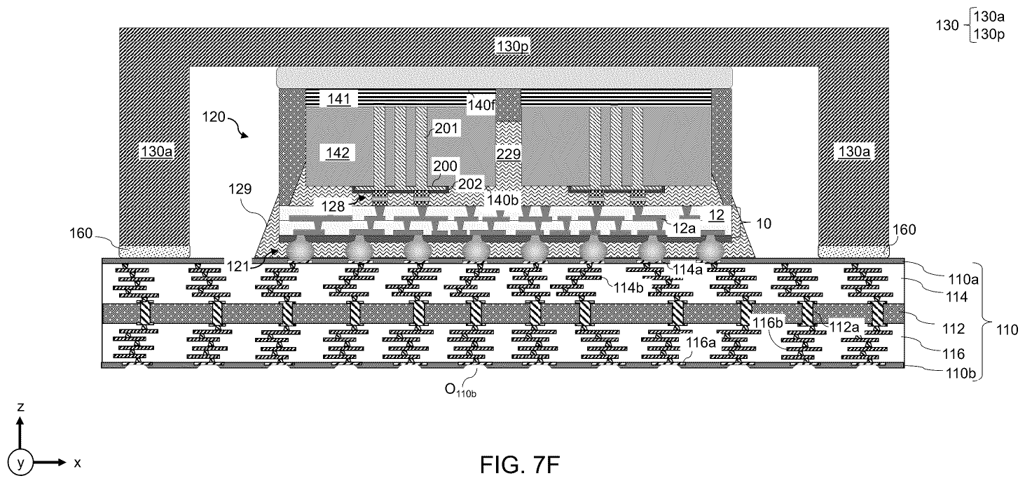

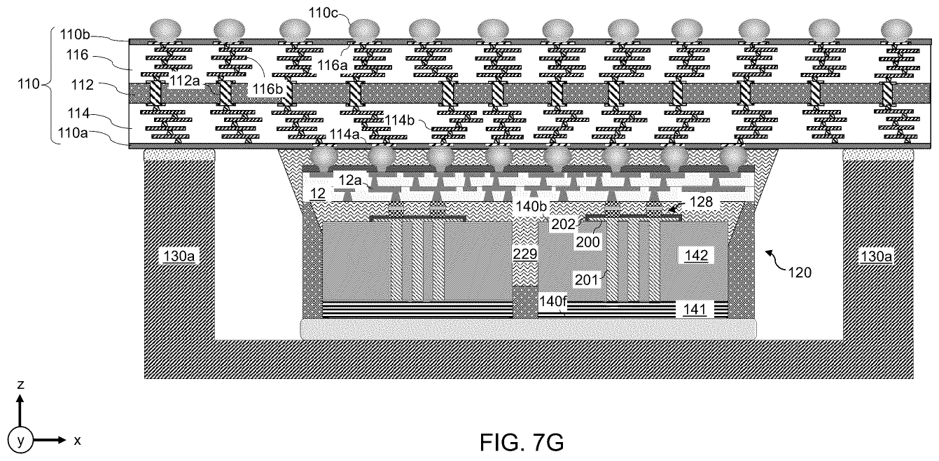

FIGS. 7A-7F illustrate various intermediate structures in a method of forming the package structure 100 according to one or more embodiments. FIG. 7A is a vertical cross-sectional view of an intermediate structure including the package substrate 110 having package substrate upper bonding pads 114a and package substrate lower bonding pads 116a, according to one or more embodiments. The package substrate 110 including the core 112, the package substrate upper dielectric layer 114, and the package substrate lower dielectric layer 116 may be provided.

The package substrate upper bonding pads 114a may be formed, for example, on an uppermost dielectric layer of the package substrate upper dielectric layer 114. The package substrate upper bonding pads 114a may be formed to contact the metal interconnect structures 114b. The package substrate upper bonding pads 114a may be formed by depositing a metal layer (e.g., copper, aluminum, or other suitable conductive materials) on the upper surface of the package substrate upper dielectric layer 114. The metal layer may then be patterned by etching (e.g., by wet etching, dry etching, etc.) to form the package substrate upper bonding pads 114a. Other suitable metal layer materials and etching processes may be within the contemplated scope of disclosure.

The package substrate lower bonding pads 116a may be formed, for example, on a lowest dielectric layer of the package substrate lower dielectric layer 116. The package substrate lower bonding pads 116a may be formed to contact the metal interconnect structures 116b. The package substrate lower bonding pads 116a may be formed in a manner similar to the manner of forming the package substrate upper bonding pads 114a (e.g., depositing a metal layer, patterning the metal layer by etching, etc.).

After formation, the package substrate upper bonding pads 114a and package substrate lower bonding pads 116a may optionally undergo a surface roughening treatment (e.g., copper zarazara (CZ) treatment). In the surface roughening treatment, a surface of the package substrate upper bonding pads 114a (e.g., a copper surface) and surface of the package substrate lower bonding pads 116a (e.g., a copper surface) may be etched by an organic acid-type microetching solution, to create a super-roughened surface (e.g., copper surface). The uniquely-roughened copper surface topography of the package substrate upper bonding pads 114a and package substrate lower bonding pads 116a may help to achieve a high copper-to-resin adhesion.

The package substrate upper passivation layer 110a and package substrate lower passivation layer 110b may then be formed on the package substrate upper bonding pads 114a and package substrate lower bonding pads 116a, respectively. In at least one embodiment, the package substrate upper passivation layer 110a and package substrate lower passivation layer 110b may each include a solder resist layer (e.g., polymer material), also referred to as a solder mask. The package substrate upper passivation layer 110a may also be referred to as the upper solder resist layer 110a, and the package substrate lower passivation layer 110b may also be referred to as the lower solder resist layer 110b.

The package substrate upper passivation layer 110a and package substrate lower passivation layer 110b may be applied concurrently. The package substrate upper passivation layer 110a and package substrate lower passivation layer 110b may be applied, for example, as a liquid photo-imageable film. The liquid photo-imageable film can be applied, for example, by silk-screening or spraying the liquid photo-imageable film onto the surface of the package substrate 110. The liquid photo-imageable film may be applied over the package substrate upper bonding pads 114a and the package substrate lower bonding pads 116a. The package substrate upper passivation layer 110a and package substrate lower passivation layer 110b may alternatively be applied as a dry-film photo-imageable film that may be vacuum-laminated onto the surface of the package substrate 110 and over the package substrate upper bonding pads 114a and package substrate lower bonding pads 116a, respectively. The package substrate upper passivation layer 110a and package substrate lower passivation layer 110b may alternatively or additionally be formed, for example, by chemical vapor deposition (CVD), physical vapor deposition (PVD), spin coating, lamination, or other suitable deposition technique.

The package substrate upper passivation layer 110a and package substrate lower passivation layer 110b may be applied to have a thickness that is slightly greater than a thickness of the package substrate upper bonding pads 114a and package substrate lower bonding pads 116a, respectively. Alternatively, the package substrate upper passivation layer 110a and package substrate lower passivation layer 110b may be applied so as to have an upper surface that is substantially coplanar with an upper surface of the package substrate upper bonding pads 114a and package substrate lower bonding pads 116a, respectively.

Openings O₁₁₀ₐ may then be formed in the package substrate upper passivation layer 110a so as to expose the upper surface of the package substrate upper bonding pads 114a. Openings O_{110b} may be formed in the package substrate lower passivation layer 110b to expose an upper surface of the package substrate lower bonding pads 116a. The openings O₁₁₀ₐ and the openings O_{110b} may be formed, for example, by using a photolithographic process. In at least one embodiment, the openings O₁₁₀ₐ and the openings O_{110b} may be formed in separate photolithographic processes.

The photolithographic process (e.g., processes) used to form the openings O₁₁₀ₐ may include forming a patterned photoresist mask (not shown) on the package substrate upper passivation layer 110a, and etching (e.g., wet etching, dry etching, etc.) the exposed upper surface of the package substrate upper passivation layer 110a through openings in the photoresist mask. The photoresist mask may be subsequently removed by ashing, dissolving the photoresist mask or by consuming the photoresist mask during the etch process.

The photolithographic process (e.g., processes) used to form the openings O_{110b} may include forming a patterned photoresist mask (not shown) on the package substrate lower passivation layer 110b, and etching (e.g., wet etching, dry etching, etc.) the exposed upper surface of the package substrate lower passivation layer 110b through openings in the photoresist mask. The photoresist mask may be subsequently removed by ashing, dissolving the photoresist mask or by consuming the photoresist mask during the etch process.

After the openings O₁₁₀ₐ are formed in the package substrate upper passivation layer 110a and the openings O_{110b} are formed in the package substrate lower passivation layer 110b, the package substrate upper passivation layer 110a (upper solder resist layer) and the package substrate lower passivation layer 110b (lower solder resist layer) may be cured such as by a thermal cure or ultraviolet (UV) cure.

FIG. 7B illustrates a vertical cross-sectional view of an intermediate structure in which the interposer module 120 may be mounted on the package substrate 110, according to one or more embodiments. The interposer module 120 may be mounted on the package substrate 110, for example, by a flip chip bonding (FCB) process. The interposer module 120 may be positioned over the package substrate 110, for example, by an electromechanical pick-and-place (PNP) machine. The C4 bumps 121 (e.g., solder bumps) on the interposer module 120 may then be lowered onto the package substrate upper bonding pads 114a through the openings O₁₁₀ₐ (see FIG. 7A) in the package substrate upper passivation layer 110a. The intermediate structure including the interposer module 120 and package substrate 110 may then be heated in order to collapse the C4 bumps 121 and bond the C4 bumps 121 to the package substrate upper bonding pads 114a. In at least one embodiment, laser assisted bonding (LAB) may be used to reflow the C4 bumps 121 so that the interposer module 120 may be attached to the package substrate upper bonding pads 114a.

FIG. 7C illustrates a vertical cross-sectional view of an intermediate structure in which the package underfill layer 129 may be formed on the package substrate 110 according to one or more embodiments. The package underfill layer 129 be formed by applying a liquid material such as an epoxy-based polymeric material to the surface of the package substrate 110. As illustrated in FIG. 7C, the package underfill layer 129 may be formed (e.g., injected) under and around the interposer module 120 and the C4 bumps 121 and onto the package substrate 110. The package underfill layer 129 may then be cured, for example, in a box oven for duration in a range from 60 minutes to 120 minutes at a temperature in a range from 120° C. to 740° C. to provide the package underfill layer 129 with a sufficient stiffness and mechanical strength.

After the package underfill layer 129 is cured, a testing process may be performed to test the intermediate structure (e.g., interposer module 120 and package substrate 110). After the testing process is completed, optional surface mounted devices (SMD) (not shown) such as DRAM devices and multilayer ceramic capacitor (MLCC) devices may be mounted on the surface of the package substrate 110 adjacent the interposer module 120. In an embodiment, a 3D stencil may be used to define which region may be covered by solder paste, and the DRAM devices and MLCC devices may be attached to the package substrate 110 by solder bumps (e.g., a reflow process). The process for attaching the DRAM devices and MLCC devices may be substantially similar as the process described above for attaching the interposer module 120 to the package substrate 110.

FIG. 7D illustrates a vertical cross-sectional view of an intermediate structure in which the TIM layer 170 may be formed on (e.g., attached to) the interposer module 120 according to one or more embodiments. The TIM layer 170 may be applied to have a width in the x-direction and length in the y-direction that are less than the completed width and length of the TIM layer 170, since the pressing of the package lid 130 will cause a deformation of the TIM layer 170 and lateral spreading of the TIM layer 170 in the x-direction and y-direction.

In at least one embodiment, a thermally conductive adhesive may or may not be applied to the upper surface of the interposer module 120, depending upon the type of TIM layer 170 is being used. A material of the TIM layer 170 may be dispensed in the form of a liquid (e.g., grease, gel, paste, etc.) onto the upper surface of the interposer module 120 (or onto the thermally conductive adhesive if present). In embodiments in which the TIM layer 170 includes a solid material, the TIM layer 170 may be pressed onto the interposer module 120 or onto the adhesive if present.

After the TIM layer 170 is formed on the interposer module 120, additional processes may be performed in preparation for attaching the package lid 130 on the package substrate. Such processes may include, for example, flux cleaning, pre-bake and plasma processes.

FIG. 7E illustrates a vertical cross-sectional view of an intermediate structure in which the adhesive layer 160 may be applied to the package substrate 110 according to one or more embodiments. The adhesive layer 160 may be dispensed onto the package substrate 110 with a dispensing tool (e.g., automated dispensing tool). The dispensing tool may dispense the adhesive layer 160 in a frame shape around the interposer module 120. At the time of application, the adhesive layer 160 may be sufficiently rigid so as to form a semi-solid bead on the surface of the package substrate 110. In at least one embodiment, a viscosity of the adhesive layer 160 at the time of application may be 50,000 centipoise (cp) or greater. The shape of the semi-solid bead may remain substantially unchanged between the time of application by the dispensing tool and the later time of attaching the package lid 130. The location of the frame shape of the adhesive layer 160 may correspond to a location of the foot portion 130a of the package lid 130. A pressing of the package lid 130 onto the adhesive layer 160 may deform the adhesive layer 160.

FIG. 7F illustrates a vertical cross-sectional view of an intermediate structure in which the package lid 130 may be attached to (e.g., mounted on) the package substrate 110 according to one or more embodiments. In at least one embodiment, the package substrate 110 with the interposer module 120 may be placed on a surface. The package lid 130 may then be positioned over the package substrate 110, for example, by an electromechanical pick-and-place (PNP) machine. The package lid 130 may then be lowered down over the interposer module 120 and onto the package substrate 110. The foot portion 130a of the package lid 130 may then be aligned with the adhesive layer 160 formed on the package substrate 110.

The package lid 130 may then be pressed downward on to the TIM layer 170 by applying a pressing force down onto the package lid 130 so that the foot portion 130a of the package lid 130 may be attached to the package substrate 110 through the adhesive layer 160. In at least one embodiment, the pressing force may cause the package lid plate portion 130p to compress the TIM layer 170. The package lid 130 may then be clamped to the package substrate 110 for a period of sufficient duration to allow the adhesive layer 160 to cure and form a secure bond between the package substrate 110 and the package lid 130. In at least one embodiment, the adhesive layer 160 is a snap-cure adhesive that may be cured by exposure to ultraviolet (UV) light.

The clamping of the package lid 130 to the package substrate 110 may additionally or alternatively be performed, for example, by using a heat clamp module. The heat clamp module may apply a uniform force across the upper surface of the package lid 130. In one or more embodiments, the heat clamp module may apply the pressing force to the package lid 130. The adhesive layer 160 may additionally or alternatively be cured, for example, in a box oven to provide the adhesive layer 160 with sufficient stiffness and mechanical strength.

FIG. 7G illustrates a vertical cross-sectional view of an intermediate structure in which a plurality of solder balls 110c may be formed on the package substrate 110 according to one or more embodiments. The plurality of solder balls 110c may be formed on the package substrate lower bonding pads 116a through the openings O110b in the package substrate lower passivation layer 110b (see FIG. 7A). The solder balls 110c may be formed, for example, by an electroplating process. The solder balls 110c may be formed, for example, so as to be located under the foot portion 130a and under the interposer module 120 and therebetween. The plurality of solder balls 110c may constitute a ball-grid array (BGA) that may allow the package structure 100 to be securely mounted (e.g., by surface mount technology (SMT)) on a substrate such as a printed circuit board and electrically coupled to the substrate.

At this point, one or more optional integrated passive devices (IPDs) (e.g., passive components) (not shown) may be mounted on the board-side surface of the package substrate 110. The optional IPDs may be mounted in a process similar to the mounting process for the SMD described above. In particular, the mounting process may include a solder reflow process for electrically coupling the IPDs to the package substrate 110. After the optional IPDs are mounted on the package substrate 110, additional processes may be used to clean the package substrate 110 and maintain the surface of the package substrate 110. Such processes may include, for example, flux cleaning, pre-bake and plasma processes. An IPD underfill layer (e.g., passive component underfill) may then be applied to the package substrate 110 and under and around the IPDs. The IPD underfill layer may include a material substantially the same as the material of the package underfill layer 129. The IPD underfill layer may also be applied and cured in a manner substantially similar to the manner of applying and curing the package underfill layer 129 described above.

After the optional IPD underfill layer is cured, one or more processes may be performed prior to final testing. The processes may include, for example, one or more inspections such as an inspection by an optical inspection system (e.g., ICOS, HEXA, etc.) and a final visual inspection. These inspections may provide a sanity check (e.g., checking z-height, package appearance, etc.) of the completed package structure 100. A final testing process may then be performed on the package structure 100.

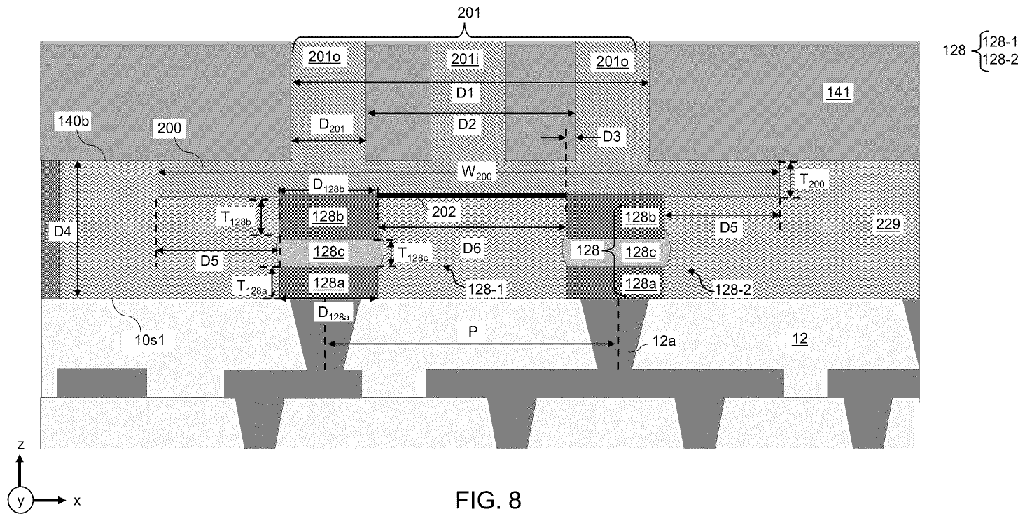

FIG. 8 is a detailed vertical cross-sectional view of the interposer module 120 having a first alternative design according to one or more embodiments. As illustrated in FIG. 8, the interposer module 120 having the first alternative design may be substantially similar to the interposer module 120 illustrated in FIGS. 1A-1C. In particular, the passivation layer 202 in the first alternative design may be substantially the same as described above with respect to FIGS. 1A-1C.

However, in the interposer module 120 having a first alternative design the passivation layer 202 may not be formed on the equipotential pad 200 outside the connection structures 128. That is, the passivation layer 202 may be formed on equipotential pad 200 only between the connection structures 128. In particular, outermost ends of the passivation layer 202 may contact an inner sidewall of the connection structures 128. A length of the passivation layer 202 in the x-direction may, therefore, be substantially equal to the distance D6 between the inner sidewalls of the connection structures 128 (e.g., in a range from 5 μm to 150 μm).

Referring to FIGS. 1A-7G, an interposer module 120 may include an interposer 10, a semiconductor die 140 on the interposer 10, wherein the semiconductor die 140 may include an equipotential pad 200 and a passivation layer 202 on the equipotential pad 200, and a plurality of connection structures 128 connecting the equipotential pad 200 to the interposer 10, wherein the passivation layer 202 may be on the equipotential pad 200 between the plurality of connection structures 128.

In one embodiment, a thickness T202 of the passivation layer 202 may be less than 1 μm. In one embodiment, the plurality of connection structures 128 may include a metal pillar 128b on the equipotential pad 200, a metal bump 128a on the interposer 10, and a solder joint 128c between the metal pillar 128b and the metal bump 128a. In one embodiment, a thickness of the equipotential pad 200 may be less than a thickness of the metal pillar 128b. In one embodiment, a thickness of the metal pillar 128b may be in a range from 5 μm to 50 μm. In one embodiment, a pitch P between the plurality of connection structures 128 may be in a range from 10 μm to 200 μm. In one embodiment, the semiconductor die 140 may include a plurality of through silicon vias (TSVs) 201 electrically coupled to the equipotential pad 200. In one embodiment, the equipotential pad 200 may be on a backside 140b of the semiconductor die 140, the semiconductor die 140 may include a front end of line (FEOL) region 141 at a frontside of the semiconductor die 140, and the TSVs 201 may extend from the equipotential pad 200 to the FEOL region 141. In one embodiment, a number of the plurality of connection structures 128 may be fewer than a number of the plurality of TSVs 201. In one embodiment, the plurality of connection structures 128 may include a pair of connection structures 128 and the plurality of TSVs 201 may include a pair of outer TSVs 201o located over the pair of connection structures 128 and an inner TSV 201i located between the outer TSVs 201o. In one embodiment, the inner TSV 201i may project from the equipotential pad 200 at a location between the plurality of connection structures 128. In one embodiment, a thickness T200 of the equipotential pad 200 may be less than 30% of the distance D4 between the semiconductor die 140 and the interposer 10.

Referring again to FIGS. 1A-7G, a method of forming an interposer module 120 may include forming a semiconductor die 140 including an equipotential pad 200, a passivation layer 202 on the equipotential pad 200, and a plurality of metal pillars 128b on the equipotential pad 200, forming an interposer 10 including a plurality of metal bumps 128a, and attaching the semiconductor die 140 to the interposer 10 by joining the plurality of metal pillars 128b to the plurality of metal bumps 128a, respectively, to form a plurality of connection structures 128, wherein the passivation layer 202 may be located on the equipotential pad 200 between the plurality of connection structures 128.

In one embodiment, the forming of the semiconductor die 140 may include forming the passivation layer 202 to have a thickness of less than 1 μm. In one embodiment, the joining of the plurality of metal pillars 128b to the plurality of metal bumps 128a may include forming a plurality of solder joints 128c between the plurality of metal pillars 128b and the plurality of metal bumps 128a, respectively. In one embodiment, the forming of the semiconductor die 140 may include forming a plurality of solder caps 128cL on the plurality of metal pillars 128b respectively, and the forming of the plurality of solder joints 128c may include reflowing the plurality of solder caps 128cL, respectively. In one embodiment, the forming of the semiconductor die 140 may further include forming a plurality of through silicon vias (TSVs) 201, and forming the equipotential pad 200 on the plurality of TSVs 201 at a backside 140b of the semiconductor die 140, wherein the plurality of TSVs 201 extend from the equipotential pad 200 to a front end of line (FEOL) region of the semiconductor die 140. The plurality of connection structures 128 may include a pair of connection structures 128 and the forming of the plurality of TSVs 201 may include forming a pair of outer TSVs 201o located over the pair of connection structures 128, and forming an inner TSV 201i located between the outer TSVs 201o.

Referring again to FIGS. 1A-7G, a package structure 100 may include a package substrate 110, an interposer module 120 on the package substrate 110, including an interposer 10, a semiconductor die 140 on the interposer 10, wherein the semiconductor die 140 may include an equipotential pad 200 and a passivation layer 202 on the equipotential pad 200, and a plurality of connection structures 128 connecting the equipotential pad 200 to the interposer 10, wherein the passivation layer 202 may be on the equipotential pad 200 between the plurality of connection structures 128, and a package lid 130 on the interposer module 120 and attached to the package substrate 110.

In one embodiment, the package structure 100 may further include a thermal interface material (TIM) layer 170 on the interposer module 120, wherein the package lid 130 may include a package lid plate portion 130p on the TIM layer 170 and a package lid foot portion 130a projecting from the package lid plate portion 130p and attached to the package substrate 110.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An interposer module comprising:
an interposer;
a semiconductor die on the interposer, wherein the semiconductor die includes an equipotential pad and a passivation layer on the equipotential pad; and
a plurality of connection structures connecting the equipotential pad to the interposer, wherein the passivation layer is on the equipotential pad between the plurality of connection structures.

2. The interposer module of claim 1, wherein a thickness of the passivation layer is less than 1 μm.

3. The interposer module of claim 1, wherein the plurality of connection structures comprises:
a metal pillar on the equipotential pad;
a metal bump on the interposer; and
a solder joint between the metal pillar and the metal bump.

4. The interposer module of claim 3, wherein a thickness of the equipotential pad is less than a thickness of the metal pillar.

5. The interposer module of claim 3, wherein a thickness of the metal pillar is in a range from 5 μm to 50 μm.

6. The interposer module of claim 1, wherein a pitch between the plurality of connection structures is in a range from 10 μm to 200 μm.

7. The interposer module of claim 1, wherein the semiconductor die comprises a plurality of through silicon vias (TSVs) electrically coupled to the equipotential pad.

8. The interposer module of claim 7, wherein the equipotential pad is on a backside of the semiconductor die, the semiconductor die comprises a front end of line (FEOL) region at a frontside of the semiconductor die, and the TSVs extend from the equipotential pad to the FEOL region.

9. The interposer module of claim 7, wherein a number of the plurality of connection structures is fewer than a number of the plurality of TSVs.

10. The interposer module of claim 7, wherein the plurality of connection structures comprises a pair of connection structures and the plurality of TSVs comprises a pair of outer TSVs located over the pair of connection structures and an inner TSV located between the outer TSVs.

11. The interposer module of claim 10, wherein the inner TSV projects from the equipotential pad at a location between the plurality of connection structures.

12. The interposer module of claim 1, wherein a thickness of the equipotential pad is less than 30% of a distance between the semiconductor die and the interposer.

13. A method of forming an interposer module, the method comprising:
forming a semiconductor die including an equipotential pad, a passivation layer on the equipotential pad, and a plurality of metal pillars on the equipotential pad;
forming an interposer including a plurality of metal bumps; and
attaching the semiconductor die to the interposer by joining the plurality of metal pillars to the plurality of metal bumps, respectively, to form a plurality of connection structures, wherein the passivation layer is located on the equipotential pad between the plurality of connection structures.

14. The method of claim 13, wherein the forming of the semiconductor die comprises forming the passivation layer to have a thickness of less than 1 μm.

15. The method of claim 13, wherein the joining of the plurality of metal pillars to the plurality of metal bumps comprises forming a plurality of solder joints between the plurality of metal pillars and the plurality of metal bumps, respectively.

16. The method of claim 15, wherein the forming of the semiconductor die comprises forming a plurality of solder caps on the plurality of metal pillars respectively, and the forming of the plurality of solder joints comprises reflowing the plurality of solder caps, respectively.

17. The method of claim 13, wherein the forming of the semiconductor die further comprises:
forming a plurality of through silicon vias (TSVs); and
forming the equipotential pad on the plurality of TSVs at a backside of the semiconductor die, wherein the plurality of TSVs extend from the equipotential pad to a front end of line (FEOL) region of the semiconductor die.

18. The method of claim 13, wherein the plurality of connection structures comprises a pair of connection structures and the forming of the plurality of TSVs comprises:
forming a pair of outer TSVs located over the pair of connection structures; and
forming an inner TSV located between the outer TSVs.

19. A package structure, comprising:
a package substrate;
an interposer module on the package substrate, comprising:
an interposer;
a semiconductor die on the interposer, wherein the semiconductor die includes an equipotential pad and a passivation layer on the equipotential pad; and
a plurality of connection structures connecting the equipotential pad to the interposer, wherein the passivation layer is on the equipotential pad between the plurality of connection structures; and
a package lid on the interposer module and attached to the package substrate.

20. The package structure of claim 19, further comprising:
a thermal interface material (TIM) layer on the interposer module, wherein the package lid includes a package lid plate portion on the TIM layer and a package lid foot portion projecting from the package lid plate portion and attached to the package substrate.
